(19) United States
(12) Patent Application Publication
(10) Pub. No.: US 2016/0072252 A1
(43) Pub. Date: Mar. 10, 2016

(54) Semiconductor Lasers

(71) Applicant: Canare Electric Co., Ltd., Aichi (JP)

(72) Inventor: Takeshi Ota, Kanagawa (JP)

(21) Appl. No.: 14/824,781

(22) Filed: Aug. 12, 2015

(30) Foreign Application Priority Data
Sep. 4, 2014 (JP) 2014-179789
Oct. 9, 2014 (JP) 2014-208296

(51) Int. Cl. H01S 5/022

(52) U.S. Cl. CPC H01S 5/02256

(57) ABSTRACT

A semiconductor laser comprises a semiconductor laser chip, a conductive mount, an insulation block, and an electrode. The semiconductor laser chip and the insulation block are bonded to a surface of the conductive mount, and an upper surface of the electrode and the semiconductor laser chip are electrically connected. The thickness of the electrode is no less than 0.3 mm.

### FIELD OF THE INVENTION

The present invention relates to semiconductor lasers, more particularly, to high power semiconductor lasers. The present invention relates to packages for the high power semiconductor lasers, more particularly, to the packages which have good heat dissipation capability. The present invention relates to power dispatching structure for the high power semiconductor laser packages. The present invention relates to insulation structure for the high power semiconductor laser packages.

### BACKGROUND OF THE INVENTION

Japanese Unexamined Patent Application Publication No. 2003-23205 (Reference 1) discloses structures of a semiconductor laser assembly. The disclosed device has a structure in which plural semiconductor laser arrays are stacked vertically. Such a device is called as vertical laser bar stacks. According to the disclosed devices, each semiconductor laser array comprises a water cooled heat sink independently, and channels of the heat sinks are connected by adhesive. The plural semiconductor laser arrays are serially connected by stacking and soldering.

Japanese Unexamined Patent Application Publication No. 2012-514860 (Reference 2) discloses so-called C-mount which is one of the packages of semiconductor lasers. The C-mount typically applied for relatively low power semiconductor lasers.

Japanese Patent No. 3800116 (Reference 3) discloses a sub mount for semiconductor lasers in which a CTE (Coefficient of Thermal Expansion) is controlled by stacking two kinds of metals.

Japanese Patent No. 5075165 (Reference 4) discloses a sub mount for semiconductor lasers in which a CTE is controlled by stacking an AlN (Aluminum Nitride) and Coppers.

Japanese Patent No. 5296977 (Reference 5) discloses a sub mount for semiconductor lasers in which a Molybdenum and Coppers are stacked to control a total CTE. This document also discloses a sub mount for semiconductor lasers in which a CTE is controlled by stacking an AlN and Coppers.

Japanese Unexamined Patent Application Publication No. 2008-283064 (Reference 6) discloses formula to determine a CTE of a material in which different kinds of materials are stacked.

Japanese Unexamined Patent Application Publication No. 2008-311556 (Reference 7) discloses a configuration in which a stress relaxation agent is added in a solder layer for connecting a semiconductor laser and sub mount.

Japanese Unexamined Patent Application Publication No. 2009-158645 (Reference 8) discloses a method to control a thermal expansion of solder by diffusing particles which has a different CTE from original solder material.

The semiconductor laser assembly described in Reference 1 has connection mechanisms among the plural water cooled heat sinks so that its assembling process is complicated and water leak risk remained. Due to electric connections among the semiconductor laser arrays are realized by soldering, it shows poor productivity and poor reliability of the electronic connections.

The semiconductor laser utilizing C mount described in Reference 2 is cheap but it only emits low power, thus this type semiconductor lasers cannot substitute vertical type laser bar stacks.

### SUMMARY OF THE INVENTION

To solve above problems the present invention comprises a semiconductor laser chip, a conductive mount, an insulation block, an upper electrode, and a lower electrode. The semiconductor laser chip and the insulation block are bonded to the first surface of the conductive mount. The upper electrode is bonded to the insulation block. An upper surface of the upper electrode and the semiconductor chip are wired by a conductive wire. The lower electrode is bonded to the second surface of the conductive mount.

The present invention provides electronic connectivity by wire bonding mechanism among plural semiconductor lasers placed on a heat sink. Thus there is no need to connect plural water cooled heat sink. Therefore the present invention provides less complicated production process and eliminates water leak risk. According to the present invention, the plural semiconductor lasers are placed on the heat sink by die bonding process which provides good productivity and high reliability.

### BRIEF DESCRIPTION OF THE DRAWINGS

The accompanying drawings form a part of the specification and are to be read in conjunction therewith. The illustrated embodiments, however, are merely examples and are not intended to be limiting. Like reference numbers and designations in the various drawings indicate like elements.

FIG. 1 is a schematic diagram of the semiconductor laser 10 as the 1^{st} embodiment of the present invention wherein (a) shows a plan view of the laser 10, and (b), (c) and (d) show partial cress-section views explaining how to fix the laser 10 to the heat sink 11.

FIG. 2 is a schematic diagram of the laser light source module 20 wherein (a) shows a plan view of the module 20, and (b) shows a diagram of a equivalent circuit of the module 20.

FIG. 3 is a schematic diagram of the connection architecture between the semiconductor laser 21 and 21.

FIG. 4 is a schematic diagram of the laser light source module 50 as the 2^{nd} embodiment of the present invention.

FIG. 5 is a schematic diagram of the heat sink 51.

FIG. 6 is a schematic diagram of the solid state laser comprising the laser light source module 50.

FIG. 7 is a schematic diagram of the semiconductor laser 60 as the 3^{rd} embodiment of the present invention wherein (a) shows a plan view of the laser 60, and (b) shows a partial cress-section view explaining how to fix the laser 60 to the heat sink 11.

FIG. 8 is a schematic diagram of the laser light source module 70 wherein (a) shows a plan view of the module 70, and (b) shows a diagram of a equivalent circuit of the module 70.

FIG. 9 is a schematic diagram of the semiconductor laser 80 as the 4^{th} embodiment of the present invention wherein (a) shows a plan view of the laser 80, (b) shows a partial cross-section view explaining how to fix the laser 80 to the heat sink 11, and (c) shows a electrode terminal 84 for the laser 80.

FIG. 10 is a schematic diagram of the laser light source module 90 wherein (a) shows a plan view of the module 90, and (b) shows a diagram of a equivalent circuit of the module 90.

FIG. 11 is a schematic diagram of the semiconductor laser 100 as the 5^{th} embodiment of the present invention wherein (a) shows a plan view of the laser 100, and (b), (c) and (d) show partial cress-section views explaining how to fix the laser 100 to the heat sink 11.

FIG. 12 is a schematic diagram of the laser light source module 110 wherein (a) shows a plan view of the module 110, and (b) shows a diagram of a equivalent circuit of the module 110.

FIG. 13 is a schematic diagram of the semiconductor laser 120 as the 6^{th} embodiment of the present invention wherein (a) shows a plan view of the laser 120, and (b), (c) and (d) show partial cress-section views explaining how to fix the laser 120 to the heat sink 11.

FIG. 14 is a schematic diagram of the laser light source module 130 as the 7th embodiment of the present invention.

FIG. 15 is a schematic diagram of the heat sink 131.

FIG. 16 is a schematic diagram of the semiconductor laser 140 as the 8^{th} embodiment of the present invention wherein (a) shows a plan view of the laser 140, and (b) and (c) show a partial cross-section view and a plan view explaining how to fix the laser 140 to the heat sink 150.

FIG. 17 is a schematic diagram of the laser light source module 160 as the 7^{th} embodiment of the present invention.

FIG. 18 is a schematic diagram of the heat sink 161.

FIG. 19 is a schematic diagram of the semiconductor laser 170 as the 10^{th} embodiment of the present invention wherein (a) shows a plan view of the laser 170, and (b) and (c) show a partial cress-section view and a plan view explaining how to fix the laser 170 to the heat sink 180.

FIG. 20 is a schematic diagram of the laser light source module 190 as the 11^{th} embodiment of the present invention.

FIG. 21 is a schematic diagram of the solid state laser 210 comprising the laser light source module 190.

FIG. 22 is a schematic diagram of the semiconductor laser 220.

FIG. 23 is a schematic diagram of the laser light source module 230 as the 12^{th} embodiment of the present invention.

FIG. 24 is a schematic diagram which shows near field patterns (a) to (e) of a variety of the laser light source modules.

FIG. 25 is a schematic diagram of the semiconductor laser 260 as the 10^{3h} embodiment of the present invention wherein (a) shows a plan view of the laser 260 and (b) shows an electrode 265 for the laser 260.

FIG. 26 is a schematic diagram of the laser light source module 270.

FIG. 27 is a schematic diagram of the semiconductor laser 280 as the 14^{th} embodiment of the present invention wherein (a) shows a plan view of the laser 280, and (b) and (c) show a partial cress-section view and a plan view explaining how to fix the laser 280 to the heat sink 180.

FIG. 28 is a schematic diagram of the bus bar 287 having different shapes.

FIG. 29 is a detailed diagram of the architecture of the mount 171, the adhesive layer 286, and the semiconductor laser chip 172.

FIG. 30 is a schematic diagram of disk laser 290 as the 16^{th} embodiment of the present invention wherein (a) shows an exploded perspective view of the laser 290 and (b) is a partial cross-section view of the laser 290.

FIG. 31 is a schematic diagram of disk laser 300 as the 17^{th} embodiment of the present invention.

FIG. 32 is a schematic diagram of thin film slab laser 310 as the 18^{th} embodiment of the present invention.

FIG. 33 is a schematic diagram of thin film slab laser 320 as the 19^{th} embodiment of the present invention.

FIG. 34 is a schematic diagram of disk laser 330 as the 20^{th} embodiment of the present invention.

FIG. 35 is a schematic diagram of thermal conductive spacer 340 as the 21^{st} embodiment of the present invention wherein (a) shows a plan view of the spacer 340, (b) shows a partial cross-section view of the spacer, and (c) shows a partial cross-section view of the laser using the spacer 340.

FIG. 36 is a schematic diagram of the mount 1 with the bonded insulation spacer 8 and thermal conductive layer 344, and, the heat sink 11 with thermal conductive layer 345 wherein (a) shows a plan view of the laser, and (b) shows a partial cress-section view explaining how to fix the laser to the heat sink 11.

### DETAILED DESCRIPTION OF THE PREFERRED EMBODIMENTS

Details of embodiments of the present invention are described below with referring to drawings. The embodiments do not restrict the present invention. The same reference symbols are provided to the same elements in the drawings.

### The First Embodiment

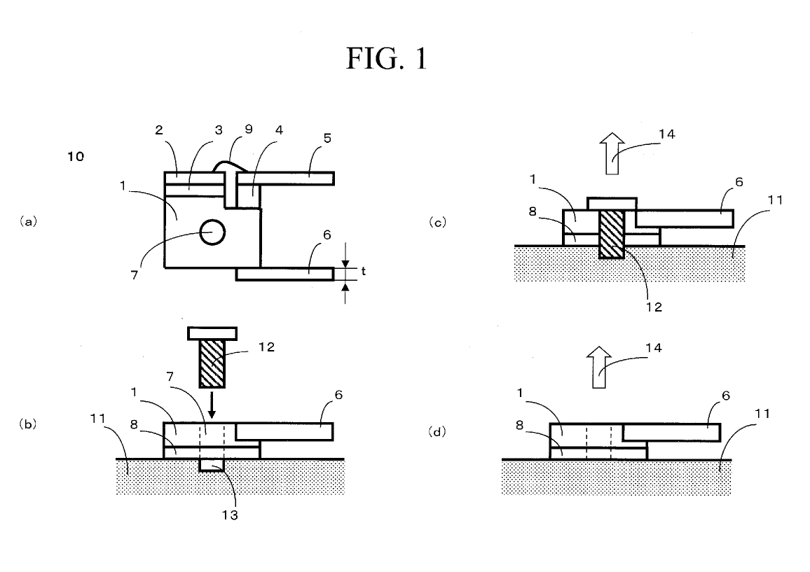

FIG. 1(a) shows semiconductor laser 10 as the 1^{st} embodiment of the present invention. The semiconductor laser 10 comprises a mount 1, a semiconductor laser chip 2, a sub mount 3, an insulation block 4, an upper electrode 5, and a lower electrode 6. The mount 1 comprises a mounting hole 7. This package architecture belongs to so-called C mount packages.

The sub mount 3 is bonded to the mount 1, and the semiconductor laser chip 2 is bonded to the sub mount 3. As a matter of convenience, the surface of the mount 1 in which the semiconductor laser chip 2 is bonded is defined as the 1^{st} surface of the mount 1. The insulation block 4 is bonded to the upper part of mount 1, and the upper electrode 5 is bonded to the insulation block 4. Also, the lower electrode 6 is bonded to the opposite surface against the 1^{st} surface of the mount 1. As a matter of convenience, the opposite surface of the 1^{st} surface of the mount 1 is defined as the 2^{nd} surface of the mount 1.

Among surfaces of the mount 1 which are perpendicular to both the 1^{st} surface and the 2^{nd} surface, the surface to be attached on a heat sink is defined as the 3^{rd} surface. Also the opposite surface against the 3^{rd} surface is defined as the 4^{th} surface.

The structure of the semiconductor laser chip 2 has no restriction. The semiconductor laser chip 2 would be ether single emitter type or multiple emitter type. The emitters would be ether single mode type or multimode type. The present embodiment adopts a semiconductor laser chip having multiple multimode emitters. In this patent specification, unless otherwise noted, a semiconductor laser chip denotes one having multiple multimode emitters.

The mount 1 is made from oxygen free copper with gold plating. The mount 1 is electrically conductive. The sub mount 3 is made from CuW with gold plating. The sub mount 3 is electrically conductive. The insulating block 4 is made from alumina based ceramics. The upper electrode 5 and the lower electrode 6 are made from oxygen free copper with gold plating.

In this patent specification, the term of plating denotes metal layer deposition by wet process.

The mount 1, the sub mount 2, the insulating block 4, the upper electrode 5, and the lower electrode 6 are simultaneously bonded together by using carbon jigs and silver soldering process. Then mount 1, the sub mount 2, the upper electrode 5, and the lower electrode 6 are simultaneously plated with gold. This production method can reduces production costs due to simultaneous plating of a mount and a sub mount. Also this production method is available for the package without the lower electrode 6.

Due to sub mounts are small; it is difficult to put electrodes for plating on the sub mounts. In this production process, first of all, the sub mount is bonded to the mount, second of all, the sub mount and the mount are plated simultaneously, and thus the above mentioned problem does not happen.

Then the semiconductor laser chip 2 is bonded to the sub mount 3 by using gold-thin alloy (AuSn). The surface of the semiconductor laser chip 2 which have laser diode structure is bonded the sub mount 3. This architecture is so-called junction down.

The upper electrode 5 and the semiconductor laser chip 2 are connected each another by a wire 9. The wire 9 is bonded to the back surface of the semiconductor laser chip 2. The back surface is opposite surface to the surface which has laser diode structure. The wire 9 is made from gold. The wire 9 may be an aggregation of plural wires, or ribbon shaped wire.

Another production method is available. In this process, first of all, the mount 1, he insulating block 4, the upper electrode 5, and the lower electrode 6 are simultaneously bonded together by using carbon jigs and silver soldering process. Second of all, the semiconductor laser chip 2 is bonded to the sub mount 3. Third of all, sub mount 3 bonded with the semiconductor laser chip 2 is bonded to the mount 1.

The semiconductor laser chip 2 utilizes GaAs (Gallium Arsenide) wafer. The sub mount 3 made form CuW (Copper Tungsten alloy) has a CTE (Coefficient of Thermal Expansion) which is almost same to the GaAs. The CuW which contains 8-11% of copper is preferable. Especially, the CuW which contains 8-11% of copper is more preferable. If the CTEs between the sub mount 3 and the semiconductor laser chip 2 are nearer, a lifetime under high power operation improves.

Thermal conductivity of the CuW, 180 W/mK, is lower than that of copper, 400 W/mK. In the above mentioned design, the sub mount 3 has a function to match the CTE to the semiconductor laser chip 3, and the mount 1 has a function to dissipate heats.

The sub mount 3 may be made from diamond particles dispersion copper. This material has a CTE matches to GaAs. In addition, the thermal conductivity of this material is as high as 500-600 W/mK.

Also the mount 1 may be made from CuW, or diamond particles dispersion copper. In this design the sub mount 3 is eliminated, and semiconductor laser chip 2 is directly bonded to the mount 1.

By contrast with standard C mounts, the semiconductor 10 has lower electrode 6. The upper electrode 5 and the lower electrode 6 have almost same dimensions. The thickness, t, of the upper electrode 5 and lower electrode 6 is preferably equal to or thicker than 0.3 mm; more preferably, they should be equal to or thicker than 0.5 mm. The thick electrodes enable to bond wires on side surface of the electrodes.

The dimensions of the semiconductor laser 10 are, for an example, as follows. The dimension of the mount 1 is 6 mm×8.4 mm×1.6 mm. The diameter of the mounting hole 7 is 2.3 mm. The dimension of the sub mount 3 is 4.2 mm×1.2 mm×0.5 mm. The dimension of the insulation block 4 is 1.4 mm×1.4 mm×1.4 mm. The dimensions of the upper electrode 5 and 6 are 6.0 mm×0.8 mm×0.65 mm.

As shown in FIG. 1 (b) and (c), the semiconductor laser 10 is screwed down on heat sink 11 with a screw 12 via an insulation spacer 8. The screw 12 is an insulation M2.0 screw. The heat sink 11 comprises a screw hole 13. The heat sink 11 is made from oxygen free copper with gold plating.

As shown in FIG. 1 (c), a laser light 14 is emitted to perpendicular to the surface of the heat sink 11.

The insulation spacer 8 is made from AlN (Aluminum Nitride). From the view point of thermal conduction, the thickness of the insulation spacer 8 is preferably equal to or thinner than 0.5 mm. From the view point of mechanical strength, the thickness of the insulation spacer 8 is preferably equal to or thicker than 0.2 mm. The insulation spacer 8 comprises a mounting hole corresponding to the mounting hole 7.

The AlN is insulation and having good thermal conductivity such as 170-230 W/mK. Due to this reason, AlN is preferable as a material of the insulation spacer 8.

The insulation spacer 8 may be bonded to the mount 1. The insulation spacer 8 and the mount 1 may be bonded by the silver particles dispersion adhesives. The design of insulation spacer 8 bonded to mount 1 has advantages such as easy handling and low thermal resistivity. This design does not require gold metallization so that production costs are less expensive.

As a base material of silver particles dispersion adhesives, a thermosetting resin or a thermoplastic resin may be adopted. As a thermosetting resin, epoxy resin may be adopted.

The insulation spacer 8 is bonded to the surface which is perpendicular to both of the 1^{st} surface and the 2^{nd} surface of mount 1 and which locates opposite to the direction of laser light 14. As described before, this surface is defined as the 3^{rd} surface.

If the insulation spacer 8 is metalized with gold, other bonding methods are applicable to bond on mount 1. An example is AuSn (gold tin alloy). As another example, gold or silver fine-particles based adhesive is applicable. The fine-particles metal based adhesives can be sintered under low temperature. The surface with gold metallization of the insulation spacer 8 and the mount 1 may be bonded together by the above mentioned adhesives. The designs provide low thermal resistivity with some penalty of production cost.

As the gold metallization design, multiple layer structure of Au/Pt/Ti/AlN is preferable. The Ti (Titanium) provides good adhesion with AlN. The Pt (Platinum) acts as barrier to avoid inter-diffusion between Ti and Au (Gold). The thickness of the Au layer, the Pt layer, and the Ti layer are 0.6 μm, 0.2 μm, and 0.1 μm, respectively.

In this patent specification, the term of metalize denotes deposition of metal by dry process.

As shown in FIG. 1 (d), the semiconductor laser chip 10, the insulation spacer 8, and the heat sink 11 may be bonded together.

In this design, the insulation spacer 8 and heat sink 11 are bonded together by silver particles dispersion adhesives. By metalizing the surface of the insulation spacer 8, other bonding method such as the AuSn alloy, the silver or gold fine particles dispersion adhesives are applicable.

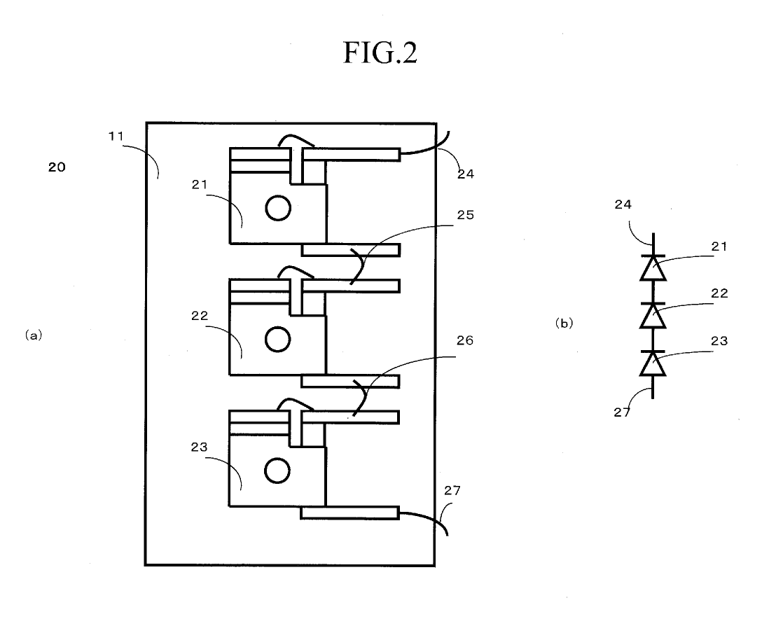

FIG. 2 shows a laser light source module 20 in which multiple semiconductor lasers 21, 22, and 23 are attached on the heat sink 11. The semiconductor lasers 21, 22, and 23 have the same structure of the semiconductor laser 10. The semiconductor lasers 21, 22, and 23 are screwed down, or bonded to the heat sink 11.

The laser light source module 20 has an equivalent function of so-called laser diode bar stack. The semiconductor lasers 21, 22, and 23 having semiconductor laser arrays provides the same light source pattern of vertical type laser diode bar stacks.

The design in which the semiconductor lasers 21, 22, and 23 bonded to the heat sink 11 may be produced by well known die bonding process. The die bonding process is widely used in semiconductor industry so that high productivity and reliability are promising.

A lower electrode of the semiconductor laser 21 and an upper electrode of the semiconductor laser 22 are connected each another via a wire 25. The lower electrode of the semiconductor laser 22 and the upper electrode of the semiconductor laser 23 are connected each another via a wire 26. Thus the semiconductor lasers 21, 22, and 23 are serially connected. FIG. 2 (b) shows equivalent circuit of the FIG. 2 (a).

The serially connected semiconductor lasers 21, 22, and 23 are connected to an external power supply by using leads 24 and 27.

High power semiconductor lasers are driven around several tens ampere of current with around 2V of drive voltages. Parallel connection of semiconductor lasers requires extremely large current with low voltage power supply. Thus such the design is not practical. On the other hand, the design showing in FIG. 2 having serial connection is more practical.

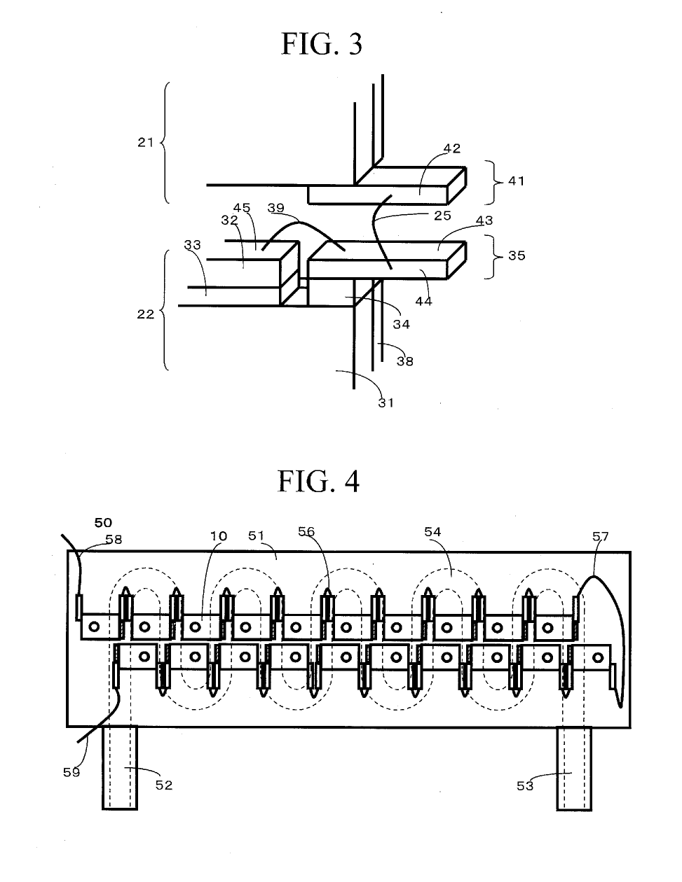

FIG. 3 shows connection structure of the semiconductor lasers 21 and 22. A side surface 42 of a lower electrode 41 of the semiconductor laser 21 is connected to a side surface 44 of an upper electrode 44 of the semiconductor 22 via a wire 26. The wire 26 is bonded to the side surfaces 42 and 44 using wire bonding process.

An upper electrode 35 is bonded to a mount 31 of the semiconductor laser 22 with an insulation block 34. A semiconductor laser chip 32 is bonded to the mount 31 with a sub mount 33. An upper surface 45 of the semiconductor laser chip 32 and an upper surface 43 of the upper electrode 35 are connected via a wire 39. The wire 39 is bonded to both of the upper surface 45 of the semiconductor laser chip 32 and an upper surface 43 of the upper electrode 35 using well known wire bonding process.

An insulation spacer 35 is bonded to the mount 31. The mount 31 is attached to the heat sink 11 via the insulation spacer 38.

The wire bonding process is established as assembling process of semiconductor devices therefore good productivity and high reliability are provided. However the wire bonding process only can connect electrodes which locate within a plane.

As shown in FIG. 3, a side surface 42 of a lower electrode 41 and the upper surface 43 of the electrode 35, for example, cannot be connected each another by the wire bonding process. To solve this problem, the present embodiment adopts the thick electrodes 35 and 41 thus the side surfaces of these electrodes provide a connection between electrodes.

### The Second Embodiment

FIG. 4 shows a laser light source module 50 as the 2^{nd} embodiment of the present invention. Twenty pieces of the semiconductor lasers 10 are attached on a water cooled heat sink 51. The semiconductor lasers 10 are screwed down on the heat sink 51.

Adjacent semiconductor lasers 10 are connected via wires 56. The connection architecture of wires 56 corresponds to architecture shown in FIG. 3. Leads 58 and 59 correspond to the leads 27 and 24 shown in FIG. 3, respectively. The leads 58 and 59 are connection means to an external power supply.

As shown in FIG. 4, the semiconductor lasers 10 form two rows. A lead 57 connects between these two rows.

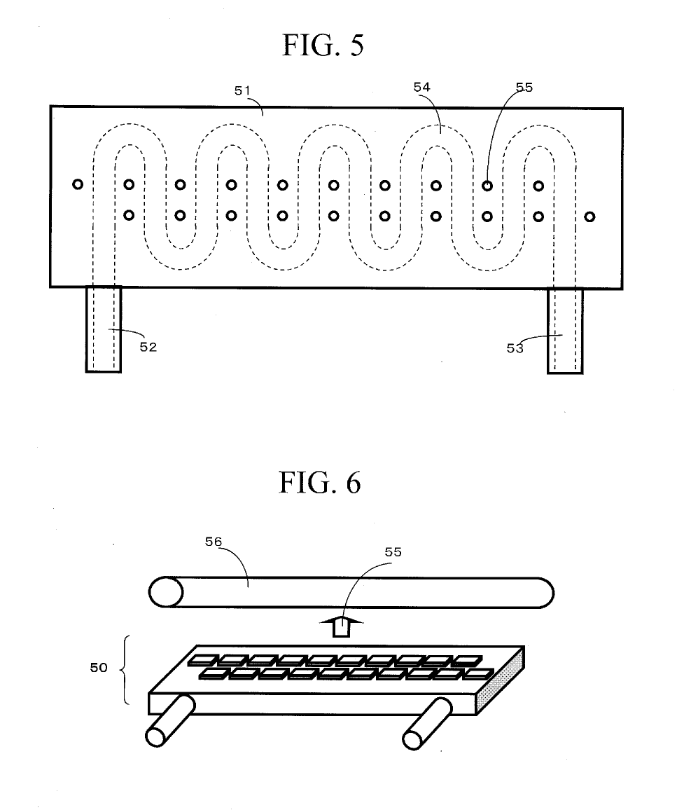

As shown in FIG. 5, The heat sink 51 comprises a water inlet 52, a channel 54, and water outlet 53. The channel 54 forms hairpin shape. Twenty screw holes 55 are built on the heat sink 51. The screw holes 55 are located along the channel.

The above design enables the channel 54 placed just under heat generation regions of the semiconductor lasers 10. At the same moment, the semiconductor lasers 10 are attached to the heat sink 51 by screws.

As shown in FIG. 6, the laser light source module 50 is applicable as a pumping source for solid state laser rod 56. This design allows to side pumping for laser rod 56 which is made from such as Nd:YAG. The configuration of the solid state laser medium is not restricted rather than the rod. Any configuration such as a slab is applicable.

### The Third Embodiment

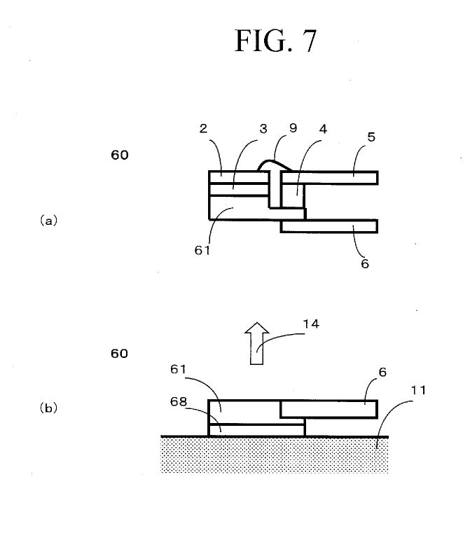

FIG. 7 (a) shows a semiconductor laser 60 as the 3^{rd} embodiment of the present invention. Compared with the semiconductor laser 10 shown in FIG. 1, the semiconductor laser 60 has a mount 61 instead of the mount 1. The mount 61 does not have the mounting hole 7.

As shown in FIG. 7 (b), the mount 61 is bonded to the heat sink 11 via an insulation spacer 68. The insulation spacer 68 does not have a mounting hole 7. The insulation spacer 68 is bonded to the mount 61.

In this configuration, the mount 61 is advantageously made compact by deletion of a mounting hole 7.

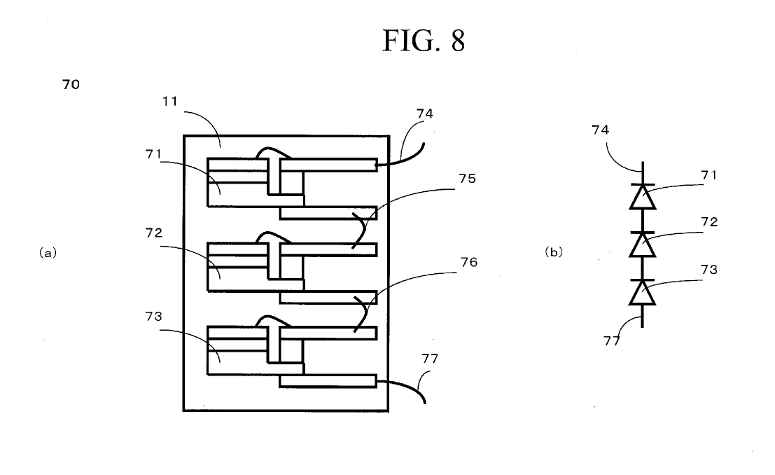

FIG. 8 (a) shows a laser light source module 70 in which plural semiconductor lasers 71, 72, and 73 are attached on the heat sink 11. The semiconductor lasers 71, 72, and 73 have the same architecture of the semiconductor laser 60 shown in FIG. 7. The semiconductor lasers 71, 72, and 73 are bonded to the heat sink 11.

Any well known die bonding process can be used to connect the semiconductor lasers 71, 72, and 73 to the heat sink 11.

A lower electrode of the semiconductor 71 and an upper electrode of the semiconductor laser 72 are connected via a wire 75. A lower electrode of the semiconductor laser 72 and an upper electrode of the semiconductor laser 73 are connected via a wire 76. This design provides serial connection among the semiconductor lasers 71, 72, and 73. FIG. 8 (c) shows an equivalent circuit of the architecture shown in FIG. 8 (b).

The semiconductor lasers 71, 72, and 73 which are connected in series, are connected to an external power supply through the lead 74 and the lead 77.

The connection architecture between the semiconductor lasers 71 and 72 corresponds to the connection architecture between semiconductor lasers 21 ad 22 shown in FIG. 3.

The present embodiment makes the semiconductor laser 60 smaller because lack of the mounting hole 7. Thus spaces among the semiconductor lasers 71, 72, and 73 are narrowed in the design shown in FIG. 8. As a result, energy density of the laser light source module 70 is increased compared to the laser light source module 20.

### The Fourth Embodiment

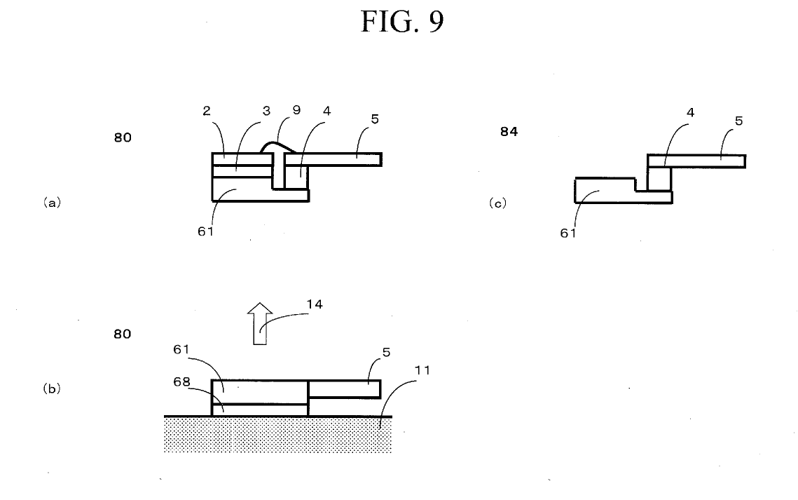

FIG. 9 (a) shows a semiconductor laser 80 as the 4^{th} embodiment of the present invention. The semiconductor laser 80 has a design where the lower electrode 6 is removed from the design of the semiconductor laser 60 shown in FIG. 7.

As shown in FIG. 9 (b), the mount 61 is bonded to the heat sink 11 via the insulation spacer 68. The insulation spacer 68 is bonded to the mount 61.

FIG. 9 (c) shows an electrode terminal 84 which is utilized with the semiconductor laser 80. The electrode terminal 84 has a design where the semiconductor laser chip 2 is removed from the design of the semiconductor laser 80. The sub mount 3 may be removed or remained. Both designs are available.

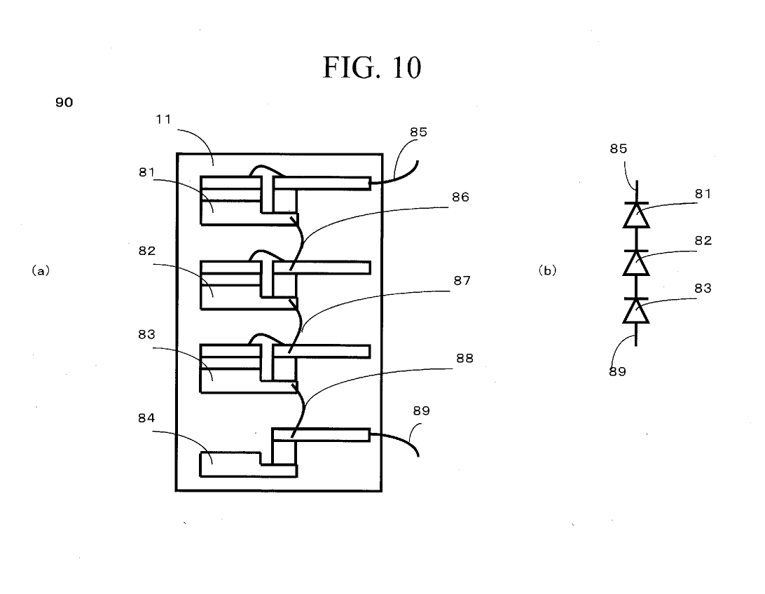

FIG. 10 (a) shows the laser light source module 90 in which plural semiconductor lasers 81, 82, and 83 are attached on the heat sink 11. The semiconductor lasers 81, 82, and 83 have the same design of the semiconductor laser 80. The semiconductor lasers 81, 82, and 83 are bonded to the heat sink 11.

To bond the semiconductor lasers 81, 82, and 83 on the heat sink 11, well known die bonding process is applicable. The die bonding process is established as assembling process of semiconductor devices therefore good productivity and high reliability are provided.

The fourth surface of a mount of the semiconductor laser 81 and a side surface of an upper electrode of the semiconductor laser 82 are connected via a wire 86. The fourth surface of a mount of the semiconductor laser 82 and a side surface of an upper electrode of the semiconductor laser 83 are connected via a wire 87. The fourth surface of a mount of the semiconductor laser 83 and a side surface of an upper electrode of an electrode terminal 84 are connected via a wire 88.

As described previously, an opposite surface to a mounting surface of a semiconductor laser against a heat sink is, for convenience, called as the fourth surface. The fourth surface corresponds to a surface from which laser light emits.

The semiconductor lasers 81, 82, and 83 does not comprise lower electrode, thus the mount of the semiconductor laser and the electrode of the adjacent semiconductor are connected via a wire. This design requires a means to connect between the semiconductor laser 83 and external power supply. To provide such a means an electrode terminal 84 is disposed. An upper electrode of the electrode terminal 84 is connected to the mount of the semiconductor laser 83, therefore a wire 89 connected to the upper electrode provides such a connection.

As described above, the semiconductor lasers 81, 82, and 83 are connected serially. FIG. 10 (b) shows equivalent circuit of the configuration shown in FIG. 10 (a).

The serially connected semiconductor lasers 81, 82, and 83 are connected with external power supply via leads 85 and 89.

The semiconductor laser 80 provides small foot print because it does not comprise any lower electrode. Thus spaces among semiconductor lasers 81, 82, and 83 are reduced as shown in FIG. 10. As a result, an energy density of the laser light source module 90 is larger than the laser light source module 70.

In addition, the semiconductor laser 80 provides simple architecture and reduced production cost.

### The Fifth Embodiment

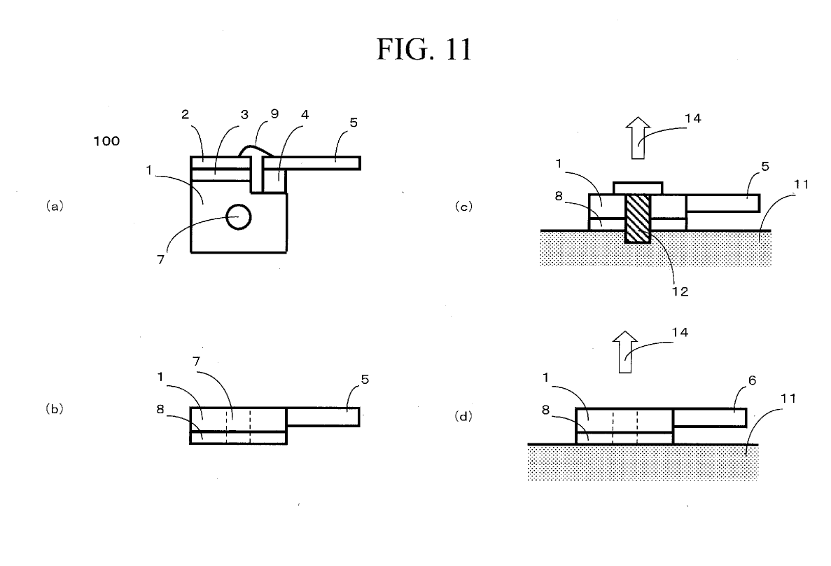

FIG. 11 (a) shows a semiconductor laser 100 as the 5^{th} embodiment of the present invention. The semiconductor laser 100 has a design where the lower electrode 6 is removed from the design of the semiconductor laser 10 shown in FIG. 1. As shown in FIG. 11 (b), the mount 1 is bonded with insulation spacer 8.

The thickness of the upper electrode 5 is preferably no less than 0.3 mm, more preferably, no less than 0.5 mm. The thick electrode enables wire bonding on the side surface of the upper electrode 5.

As shown in FIG. 11 (c), the semiconductor laser 100 is attached on the heat sink 11 using screw 12. The screw 12 is insulation screw with M2.0. The heat sink 11 comprises the screw hole 13.

As shown in FIG. 11 (d), the semiconductor laser 100 may be bonded to the heat sink 11.

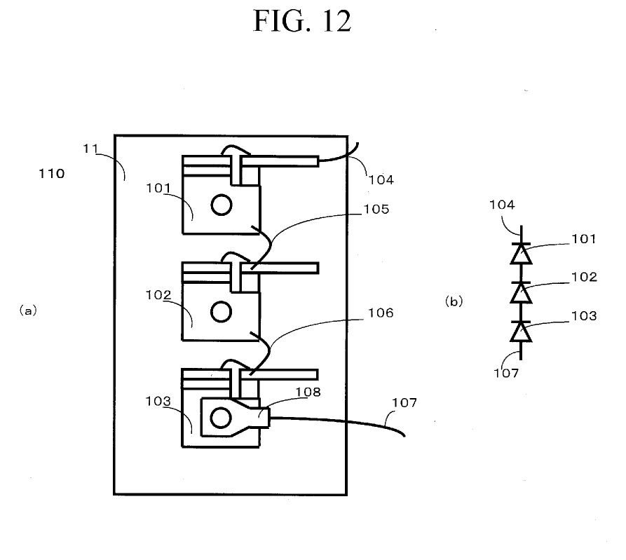

FIG. 12 (a) shows the laser light source module 110 in which the semiconductor lasers 101, 102, and 103 are attached on the heat sink 11. The semiconductor lasers 101, 102, and 103 have the same design of the semiconductor laser 110. The semiconductor lasers 101, 102, and 103 are attached on the heat sink 11 using the insulation screw or the bonding.

A conductive mount of the semiconductor laser 101 and an electrode of the semiconductor laser 102 are connected via a wire 105. A conductive mount of the semiconductor laser 102 and an electrode of the semiconductor laser 103 are connected via a wire 106. As described previously, the fourth surface of the conductive mount and the side surface of the electrode are connected.

According to the above design, the semiconductor lasers 101, 102, and 103 are serially connected. FIG. 12 (b) shows an equivalent circuit of the design shown in FIG. 12 (a).

The serially connected semiconductor lasers 101, 102, and 103 are connected to external power supply by leads 104 and 107. The lead 107 having a contact electrode 108 is attached on the conductive mount of the semiconductor laser 103 using the insulation screw or the bonding.

### The Sixth Embodiment

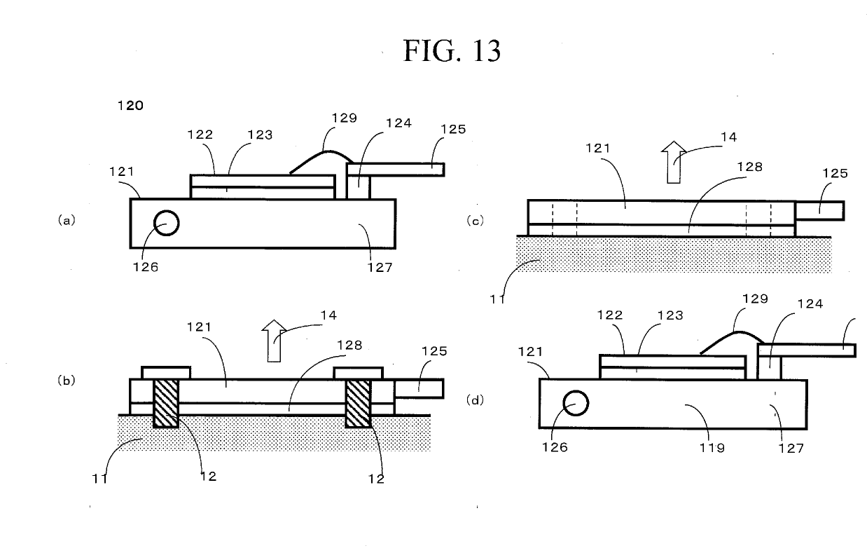

FIG. 13 (a) shows a semiconductor laser 120 as the 6^{th} embodiment of the present invention. The semiconductor laser 120 is a derivative of the semiconductor laser 10. The semiconductor laser 120 comprises a mount 121, a semiconductor laser chip 122, a sub mount 123, an insulation block 124, and an electrode 125. The mount 121 comprises mounting holes 126 and 127.

The sub mount 123 is bonded to the mount 121, and the semiconductor laser chip 122 is bonded to the sub mount 123. The insulation block 124 is bonded to the mount 121, and the electrode 125 is bonded to the insulation block 124.

The electrode 125 and the semiconductor laser chip 122 is connected via a wire 129. The wire 129 is bonded to a back surface of the semiconductor laser 122, that is, an opposite surface to the surface contains laser structure. The wire 129 is made from gold. The plural wires 129 may be disposed. The wire 129 may have ribbon shape.

Typical dimension of the semiconductor laser 120 is, for example, as follows. The dimension of the mount 121 is 20 mm×4.0 mm×2.2 mm. The diameter of the mounting hole 127 is 2.3 mm. The dimension of the sub mount 123 is 11.0 mm×2.0 mm×0.2 mm. The dimension of the electrode 125 is 7.0 mm×2.2 mm×0.8 mm.

As shown in FIG. 13 (b), the semiconductor laser 120 is attached on the heat sink 11, via an insulation spacer 128 using the two screws 12. The insulation spacer 128 may be bonded to the mount 121 of the semiconductor laser 120.

As shown in FIG. 13 (c), the semiconductor laser 120 may be bonded to the heat sink 11 via the insulation spacer 128.

The design of the semiconductor laser 120 which has two mounting holes 126 and 127 is distinctive as compared with conventional C mount. These two mounting holes 126 and 127 avoid rotation of the semiconductor laser 120 against the heat sink 11.

FIG. 13 (d) shows a feature of the present embodiment, that is, the mounting holes 126 and 127 are placed with the exception of immediately beneath region 119.

The immediately beneath region 119 denotes the region on the 3^{rd} surface of the mount 121 which exists between two perpendicular lines to the 1^{st} surface of the mount 121 drawing from both ends of the semiconductor laser chip 122.

The immediately beneath region 119 locates in heat transfer path between from the semiconductor laser chip 122 to the heat sink 11. By excluding the mounting holes 126 and 127 from the immediately beneath region 119, heat dissipation capability is improved.

A number of the mounting holes of the mount 121 is not restricted. The number may be two or over.

### The Seventh Embodiment

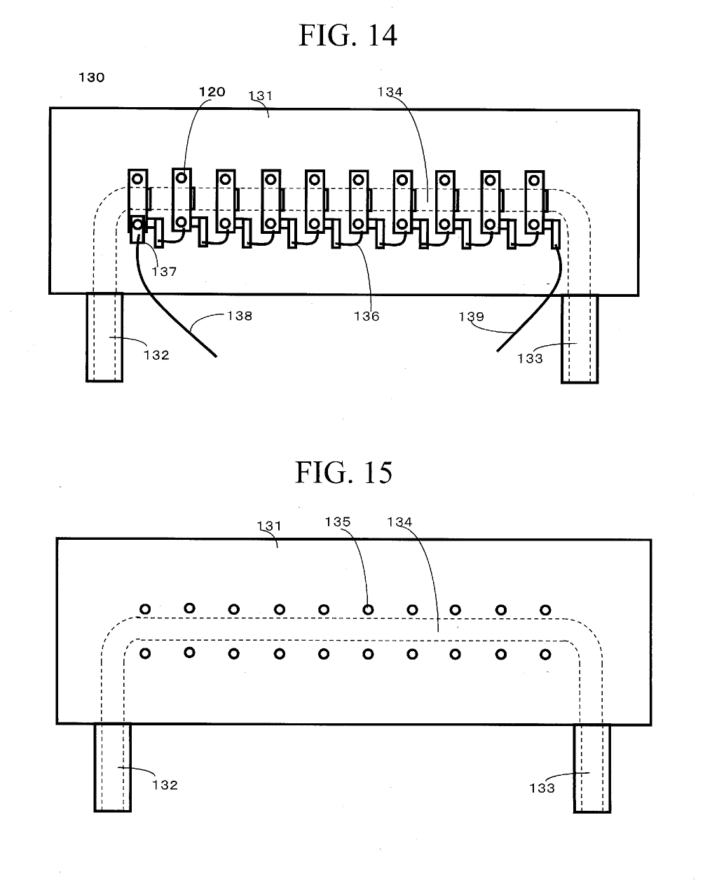

FIG. 14 shows a laser light source module 130 as the 7^{th} embodiment of the present invention. Ten semiconductor lasers 120 are attached on a water cooled heat sink 131. The semiconductor lasers 120 are attached on the water cooled heat sink 131 using insulation screws.

Between the two adjacent semiconductor lasers 120 are connected via a wire 136. The wire 136 connects a side surface of an electrode of certain semiconductor laser and a mount of the adjacent semiconductor laser.

Leads 138 and 139 are connected to an external power supply. The lead 138 comprises contact electrode 137 which is attached to the semiconductor laser using screw.

As shown in FIG. 15, The heat sink 131 comprises a water inlet 132, a channel 134, and a water outlet 133. The channel 134 is straight lined with the total twenty screw holes 135 on either side.

The above design enables the channels 134 placed just under heat generation regions of the semiconductor lasers 120. At the same moment, the semiconductor lasers 120 are attached on the water cooled heat sink 131 by screws.

The laser light source 130 may substitute the laser light source 50 in configuration shown in FIG. 6.

### The Eighth Embodiment

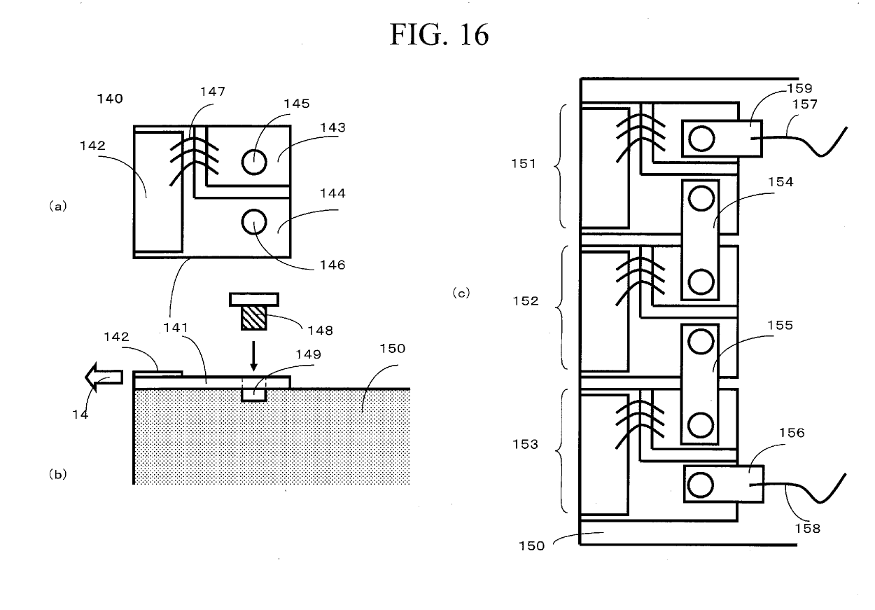

FIG. 16 (a) shows a semiconductor laser 140 as the 8^{th} embodiment of the present invention. The semiconductor laser 140 comprises a mount 141 and a semiconductor laser chip 142. The mount 141 comprises mounting holes 145 and 146.

The mount 141 is an insulation mount made from AlN (Aluminum Nitride). The dimension of the mount 141 is 15.0 mm×12.0 mm. The both surface of the mount 141 is plated with relatively thick copper. The thickness of the AlN and copper are 400 μm and 50-85 μm, respectively. By adjusting the thicknesses of the AlN and the copper, a CTE of the mount 141 varies. Appropriate design provides the mount 141 which has a almost same CTE of GaAs (Gallium Arsenide). This configuration is publically known.

A surface of the mount 141 where the semiconductor laser chip 142 is bonded is, for convenience, defined as an upper surface of the mount 141. The upper surface of the mount 141 has patterned metals made from the plated copper. Electrodes 143 and 144 are formed by these patterned metals. The copper is plated with gold. A region of the mount 141 where the semiconductor laser chip 142 is bonded may be metalized by gold tin alloy. The thickness of the gold tin alloy is between 3 and 5 μm.

The semiconductor laser 142 is bonded to the mount 141 in the manner of the junction down. A back surface of the semiconductor laser 142 and the electrode 143 are connected via a wire 147. The wire 147 may be an aggregation of plural wires or ribbon shaped wire.

As shown in FIG. 16 (b), the semiconductor laser 140 is attached on a heat sink 150 using screws 148. The heat sink 150 comprises screw holes 149. The mount 141 is attached on the heat sink 150 by engaging the screw 148 and the screw hole 149.

As shown in FIG. 16 (c), semiconductor lasers 151, 152, and 153 are attached. The semiconductor lasers 151, 152, and 153 have the same design of the semiconductor laser 140.

The semiconductor lasers 151 and 152 are connected via a bus bar 154. The semiconductor lasers 152 and 153 are connected via a bus bar 155. A lead 157 having a contact electrode 159 and a lead 158 having a contact electrode 156 provide connection among serially connected semiconductor lasers 151, 152, and 153 and an external power supply. The laser light 14 is emitted to the direction of parallel to a surface of the heat sink 150 where screw holes 149 are disposed.

The semiconductor laser 140 may be bonded to the heat sink 150. In this design, the screw holes 145 and 146 are applicable for attaching bus bars 154 and 155 having contact electrode 159 and 156, respectively.

The semiconductor laser 140 which is formed by patterning metals on the insulation substrate has an advantage that its production is easy. Due to the semiconductor laser 140 has two mounting holes so that rotation of the semiconductor laser 140 against the heat sink 150 is prevented. The mounting holes 145 and 146 correspond to an anode and a cathode of the semiconductor laser, thus electrical contact for semiconductor is easily formed.

Due to the mounting holes 145 and 146 are disposed at the opposite side of the direction of the laser light 14, the width of the mount 141, that is, the length of the mount 141 perpendicular to the direction of the laser light 14, becomes short. As a result, the semiconductor lasers 140 are attached at high density.

### The Ninth Embodiment

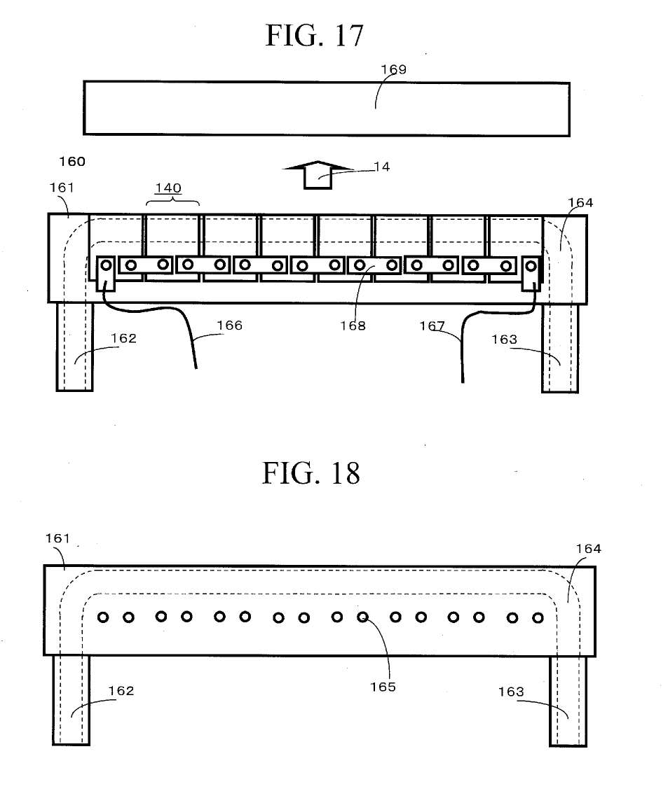

FIG. 17 shows a laser light source module 160 as the 9^{th} embodiment of the present invention. Eight semiconductor lasers 140 are attached on a water cooled heat sink 161. The semiconductor lasers 140 are attached on the water cooled heat sink 131 using insulation screws.

Between adjacent semiconductor lasers 140 are connected via bus bar 168. Leads 166 and 167 are connected to an external power supply.

The laser light 14 from the laser light source module 160 irradiates solid state laser medium 169.

shown in FIG. 18, the heat sink 161 comprises a water inlet 162, a channel 164, and a water outlet 163. The channel 164 is straight lined with the total eighteen screw holes 165 on one side.

The above design enables the channels 164 placed just under heat generation regions of the semiconductor lasers 140. At the same moment, the semiconductor lasers 140 are attached on the water cooled heat sink 161 by screws.

### The Tenth Embodiment

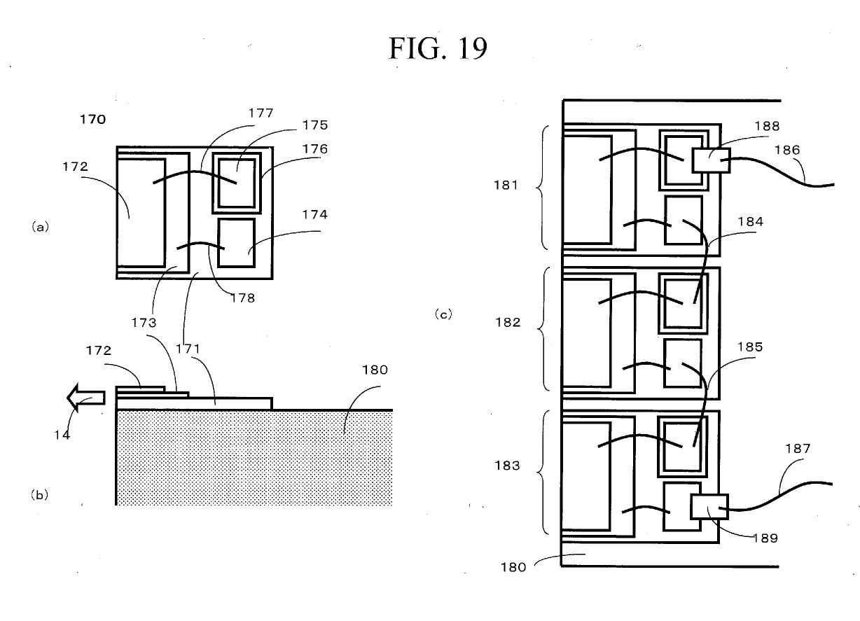

FIG. 19 (a) shows a semiconductor laser 170 as the 10^{th} embodiment of the present invention. The semiconductor laser 170 comprises a mount 171 and a semiconductor laser chip 172, a sub mount 173, electrodes 174, 175, and an insulation plate 176.

The mount 171 is an insulation mount made from AlN. The dimension of the mount 1711 is 8.4 mm×6.0 mm. The both surfaces of the mount 171 are metalized based on gold. The thickness of the AlN is 200 μm. The metallization structure is Au/Pt/Ti/AlN. The thickness of Au, Pt, and Ti are 0.6 μm, 0.2 μm, and 0.1 μm, respectively.

The insulation plate 176 is an insulation mount made from AlN. The dimension of the mount 171 is 2.5 mm×2.5 mm. The both surfaces of the mount 176 are metalized based on gold. The thickness of the AlN is 200 μm. The metallization structure is Au/Pt/Ti/AlN. The thickness of Au, Pt, and Ti are 0.6 μm, 0.2 μm, and 0.1 μm, respectively.

The mount 171 and the insulation plate 176 are fabricated simultaneously. First of all, a large AlN substrate is metalized with gold. Second of all, many mounts 171 and insulation plates 176 are cut down and haul them out.

The sub mount 173 is made from CuW which has close CTE of GaAs. The dimension of the sub mount 173 is 8.0 mm×3.0 mm. The thickness of the sub mount 173 is 0.2 mm. The sub mount 173 is plated with gold.

The dimensions of the electrodes 174 and 175 are 2.0 mm×2.0 mm. The electrodes 174 and 175 are made from oxygen free copper plated with gold.

The semiconductor laser chip 172 is bonded to the sub mount 173 in the manner of the junction down. The sub mount 173 is bonded to the mount 171. The insulation plate 176 is bonded to the mount 171. The electrode 175 is bonded to the insulation plate 176. The electrode 174 is bonded to the mount 171.

As the bonding process mentioned above, low temperature sintering process of gold or silver fine particles are applicable. A silver particles dispersion adhesive is also applicable. Further, Gold thin alloy is applicable.

A back surface of the semiconductor laser chip 172 and the electrode 175 are connected via a wire 177. The sub mount 173 and the electrode 174 are connected via a wire 178. These connections are established by wire bonding process. The wires 177 and 178 are made from gold.

The each wire 177 and 178 may be an aggregation of plural wires, or ribbon shaped wire.

The sub mount 173 and the electrode 174 are connected via a gold metalized layer on the mount 171. However, due to the gold metalized layer is relatively thin; an electric resistivity between the sub mount 173 and the electrode 174 is relatively large. To solve this problem, the wire 178 is disposed.

As shown in FIG. 19 (b), the semiconductor laser 170 is bonded to a heat sink 180. The heat sink 180 is made from oxygen free copper plated with gold. The semiconductor laser 170 and the heat sink 180 are bonded using the gold or silver fine particles. Also the silver particle dispersion adhesive or the gold tin alloy is applicable.

The bonding process using the gold fine particles or the silver fine particles provides low thermal resistivity. The gold tin alloy provides better mechanical strength.

As shown in FIG. 19 (c), semiconductor lasers 181, 183, and 183 are attached on a heat sink 180. The semiconductor lasers 181, 183, and 183 are based on the design of the semiconductor laser 170.

The semiconductor lasers 181 and 182 are connected via a wire 184. The semiconductor lasers 182 and 183 are connected via a wire 155. A lead 186 having a contact electrode 188 and a lead 187 having a contact electrode 189 provide connection among serially connected semiconductor lasers 181, 182, and 183 and an external power supply. The laser light 14 is emitted to the direction of parallel to a surface of the heat sink 180 where the semiconductor lasers 170 are disposed.

The design shown in FIG. 19 (c) is applicable to the design shown in FIG. 17 to construct a laser light source module. The laser light source module is applicable to the solid state laser.

The contact electrodes 188 and 189 are bonded to the electrodes of the semiconductor lasers 181 and 183, respectively.

The above mentioned semiconductor laser 170 eliminates any hole. Thus the semiconductor lasers are produced easily. The semiconductor laser 170 comprises the sub mount 173 which has close CTE of the semiconductor laser chip 172. As a result, long life operation of the semiconductor laser chip 172 is available.

Simultaneous fabrication of the mount 171 and the insulation plate 176 reduces production cost.

The semiconductor laser 170 comprising the mount 171 and the insulation plate 176 without metallization are also available. In this configuration, the bonding between sub mount 172 and the mount 171, the bonding between the electrode 174 and the mount 171, the bonding between the electrode 175 and the insulation plate 176, and the bonding between the mount 171 and the insulation plate 176 may be done by using silver particle dispersion adhesives.

The above design eliminates gold metallization, thus production costs of the mount 171 and the insulation plate 176 are reduced.

### The Eleventh Embodiment

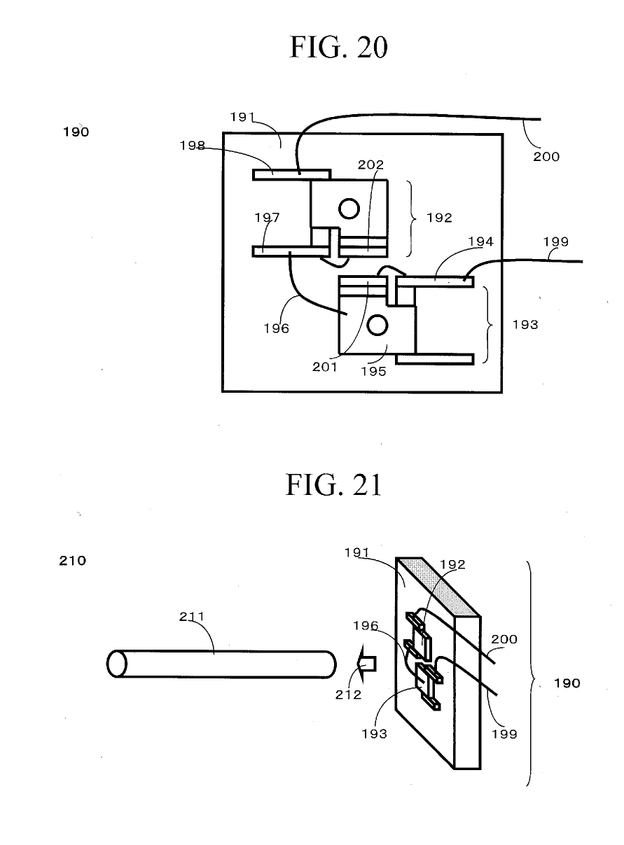

FIG. 20 shows a laser light source module 190 as the 11^{th} embodiment of the present invention. Two semiconductor lasers 192 and 193 are attached on a heat sink 191 using insulation screws. The semiconductor lasers 192 and 193 have the same design of the semiconductor laser 10.

The present embodiment provides a configuration in which a semiconductor laser chip 202 of the semiconductor laser 192 and the semiconductor laser chip 203 of the semiconductor laser 193 are disposed in a manner of face to face. This configuration allows approximating laser lights from the semiconductor lasers 202 and 201.

A lead 199 is connected to an upper electrode 194 of the semiconductor laser 193. A mount 195 of the semiconductor laser 193 is connected to an upper electrode 197 of the semiconductor laser 192 via a wire 196. A lead 200 is connected to a lower electrode 198 of the semiconductor laser 192.

The semiconductor lasers 192 and 193 are serially connected using the above mentioned design. The leads 199 and 200 connect the semiconductor lasers 192 and 193 to a power supply.

FIG. 21 shows solid state laser 210 having the laser light source module 190. The laser light 212 from the semiconductor lasers 192 and 193 are guided to one end surface of a solid state laser rod 211. This design is so-called end pumping.

As described above the laser light source module 190 having two semiconductor laser chips 202 and 201 in close proximity. Thus the laser light 212 is guided to the end surface of the solid state laser rod 211 with high coupling efficiency.

The present embodiment utilizes the semiconductor lasers 192 and 193 which have the same design of the semiconductor laser 10. Other type semiconductor lasers such as standard C-mount lasers may be applicable to the present embodiment. A C-mount laser may be attached with another C-mount laser in a manner of face to face on the heat sink 191.

This design also allows guiding laser light from the two C-mounting lasers to the end surface of the solid state laser rod with high coupling efficiency.

### The Twelfth Embodiment

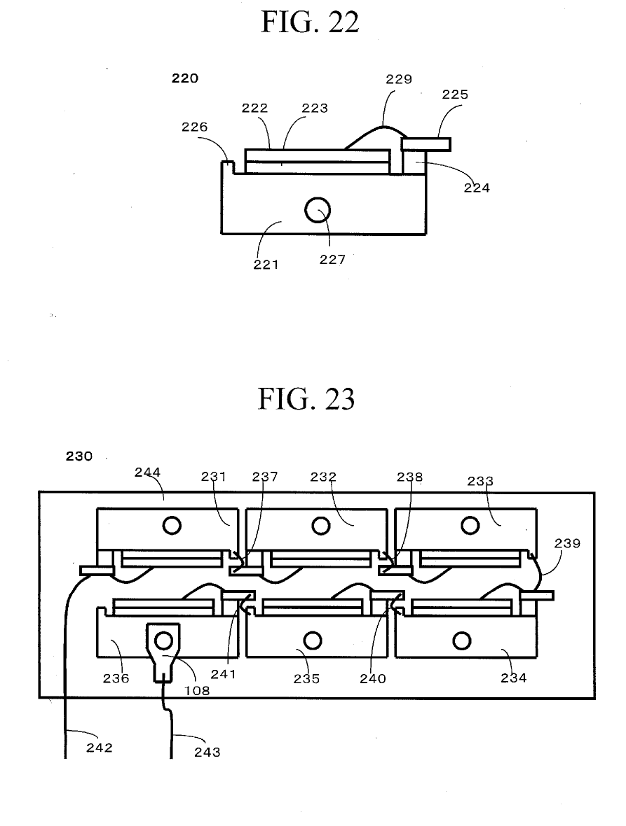

FIG. 22 shows a semiconductor laser 220. The semiconductor laser 220 is a derivative of the semiconductor laser 10. The semiconductor laser 220 comprises a mount 221, a semiconductor laser chip 222, a sub mount 223, an insulation block 224, and an electrode 225. The mount 221 comprises a mounting hole 227. The mount 221 comprises a convex portion 226.

The sub mount 223 is bonded to the mount 221. The semiconductor chip 222 is bonded to the sub mount 223. The insulation block 224 is bonded to the mount 221. The electrode 225 is bonded to the insulation block 224. The semiconductor laser chip 222 and the electrode 225 are connected via a wire 229.

FIG. 23 shows a laser light source module 230 as the 12^{th} embodiment of the present invention. Six pieces of semiconductor lasers 231, 232, 233, 234, 235, and 236 are attached on a heat sink 244 using insulation screws. The semiconductor lasers 231, 232, 233, 234, 235, and 236 have the same design of the semiconductor laser 220.

The semiconductor lasers 231, 232, 233, 234, 235, and 236 are serially connected via wires 237, 238, 239, 240, and 241. Leads 242 and 243 connect the serially connected semiconductor lasers 231, 232, 233, 234, 235, and 236 to a power supply.

The convex portion 226 of the mount 221 is applicable to connect an electrode of the adjacent semiconductor laser. Also the convex portion 226 provides mechanical protection for the semiconductor laser chip 222.

The present embodiment provides a configuration in which a semiconductor laser chip of the semiconductor laser 231 and a semiconductor laser chip of the semiconductor laser 236 are placed in a manner of face to face. Also, a semiconductor laser chip of the semiconductor laser 232 and a semiconductor laser chip of the semiconductor laser 235 are placed in a manner of face to face. Further, a semiconductor laser chip of the semiconductor laser 233 and a semiconductor laser chip of the semiconductor laser 234 are placed in a manner of face to face.

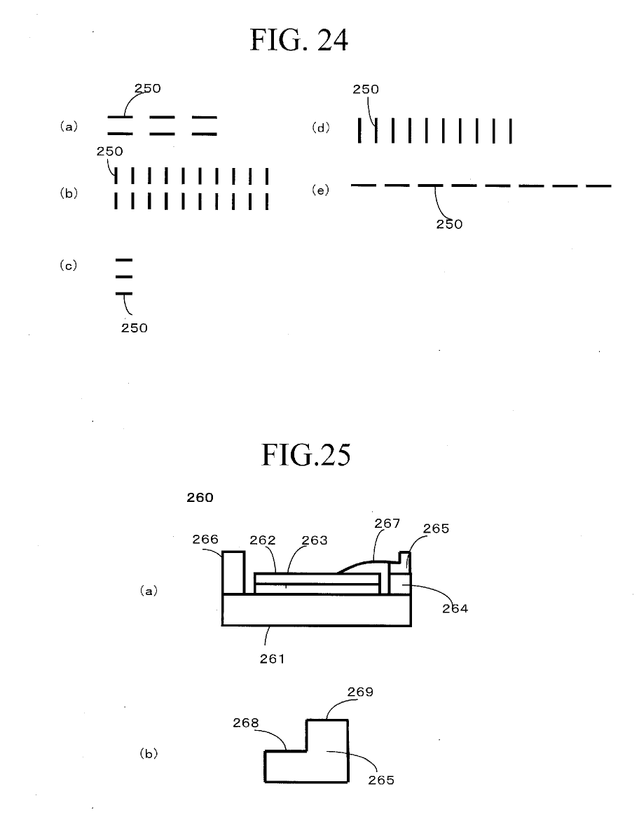

FIG. 24 (a) is a schematic diagram which shows a near field pattern of the laser light source module 230. This near field pattern has two rows of three light-emitting parts 250.

The present embodiment provides two semiconductor lasers 231 and 236 in close proximity. Thus two rows of light-emitting parts are also in close proximity as shown in FIG. 24 (a). As a result, light emission density of the laser light source module 230 increases.

FIG. 24 (b) shows schematically the near field pattern of the laser light source module 50 shown in FIG. 4. FIG. 24 (c) shows schematically the near field pattern of the laser light source module 90 shown in FIG. 10. FIG. 24 (d) shows schematically the near field pattern of the laser light source module 130 shown in FIG. 14. FIG. 24 (3) shows schematically the near field pattern of the laser light source module 160 shown in FIG. 17.

The mount 221 of the semiconductor laser 220 comprises a mounting hole. The number of the mounting holes may be two or over. The mount may have no mounting hole. In this case, the mount is boned on the heat sink.

### The Thirteenth Embodiment

FIG. 25 (a) shows a semiconductor laser 260 as the 13^{th} embodiment of the present invention. The semiconductor laser 260 is a derivative of the semiconductor laser 10. The semiconductor laser 260 comprises a mount 261, a semiconductor laser chip 262, a sub mount 263, the 1^{st} insulation block 264, an electrode 265, and the 2^{nd} insulation block 266. The mount 261 may have a mounting hole.

The sub mount 263 is bonded to the mount 261. The semiconductor chip 262 is bonded to the sub mount 263. The 1^{st} and the 2^{nd} insulation blocks 264 and 266 are bonded to the mount 261. The electrode 265 is bonded to the 1^{st} insulation block 264. The semiconductor laser chip 262 and the electrode 265 are connected via a wire 267. The 1^{st} and the 2^{nd} insulation blocks 264 and 266 are disposed at the both side of the semiconductor laser chip 262 on the mount 261.

The height of the 2^{nd} insulation block 266 is equivalent to sum of the height of the 1^{st} insulation block and the height of the electrode 265.

As shown in FIG. 25 (b), the electrode 265 forms step-wise shape and have L-shaped cross-section. The wire 267 is bonded to a lower surface 268 of the electrode 265. An upper surface 269 of the electrode 265 is to protect.

From different view point on the shape of the electrode 265, the thickness of the electrode 265 corresponding to the surface 268 is thin, and the thickness of the electrode 265 corresponding to the surface 269 is thick.

According to the design of the semiconductor laser 260, the electrode 265 and the 2^{nd} insulation block 266 protect the semiconductor laser chip 266 and the wire 267.

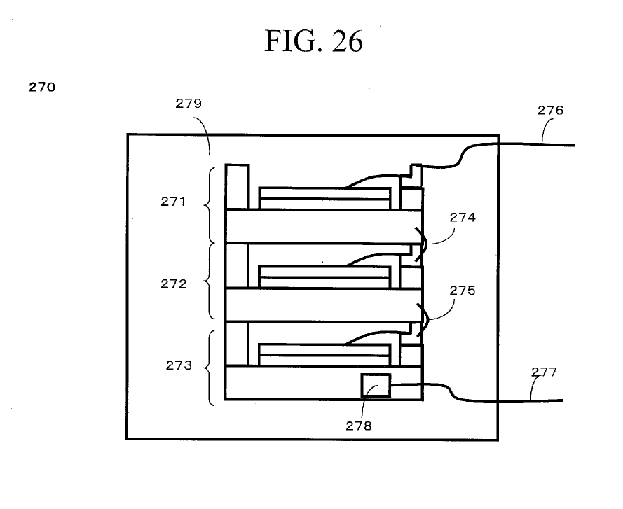

FIG. 26 shows a laser light source module 270. The laser light source module 270 comprises semiconductor lasers 271, 272, and 273 bonded to a heat sink 279. The semiconductor lasers 271, 272, and 273 have the same design of the semiconductor laser 260.

The semiconductor lasers 271 and 272 are connected via a wire 274 and the semiconductor lasers 272 and 273 are connected via a wire 275, respectively. These connections make serial connection of the semiconductor lasers 271, 272, and 273.

The serially connected semiconductor laser 271, 272, and 273 are connected to an external power supply via leads 276 and 277. The lead 277 comprises a contact electrode 278. The contact electrode 278 is bonded to the mount of the semiconductor laser 273.

The semiconductor lasers 271, 272, and 273 are mechanically contacted in the design of the laser light source module 270. As a result, high laser light density is obtained. The 1^{st} insulation block 274, the electrode 265, and the 2^{nd} insulation block 266 act as spacers among the semiconductor lasers 260.

The electrode 265 and the 2^{nd} insulation block 266 protect the semiconductor 262 and the wire 267.

The wire 274 and 275 provide high reliability of the electric connection.

As a different form of the laser light source module, the semiconductor lasers 271, 272, and 273 are attached with specified interval. In this design, the wires 274 and 275 must be disposed for electric connections.

The semiconductor laser 260 is applicable to the laser light source module 190 shown in FIG. 20. The semiconductor laser 260 may substitute the semiconductor lasers 192 and 193. This design provides narrower spacing between two semiconductor lasers.

The semiconductor laser 260 is applicable to the laser light source module 230 shown in FIG. 23. The semiconductor laser 260 may substitute the semiconductor lasers 231, 232, 233, 234, 235, and 236. This design provides narrower spacing between two confronted semiconductor lasers.

### The Fourteenth Embodiment

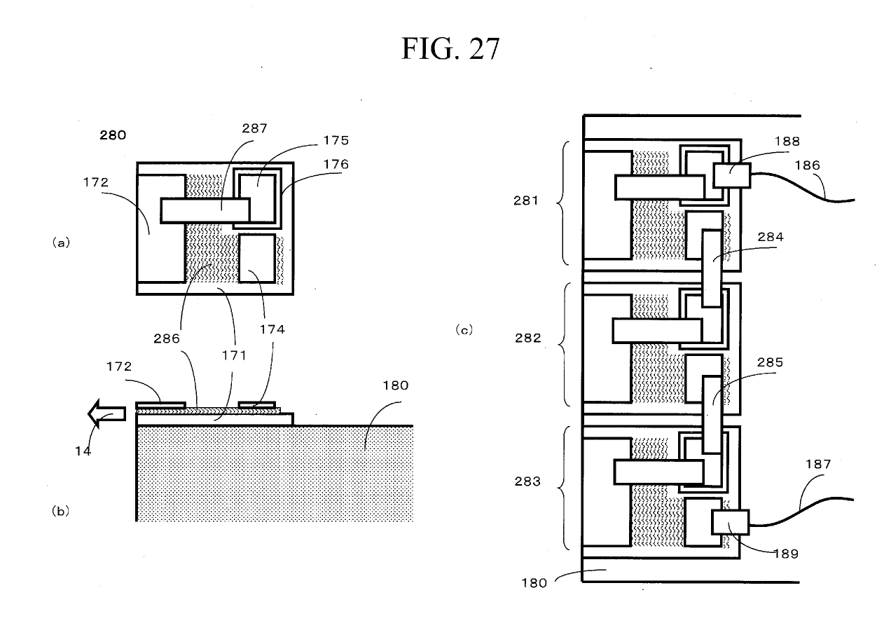

FIG. 27 (a) shows a semiconductor laser 280 as the 14^{th} embodiment of the present invention. The semiconductor laser 260 is a derivative of the semiconductor laser 170 shown in FIG. 19. The semiconductor laser 280 comprises an adhesive layer 286 instead of the sub mount 273.

The adhesive layer 286 is made from a low temperature sintered compact of gold or silver fine particles. Also the adhesive layer 286 may be made from silver particles dispersion adhesive or gold tin alloy. The adhesive layer 286 is formed by the method such as screen printing.

The mount 171 is gold metalized. The metallization of the surface to be bonded the semiconductor laser chip 172 may be omitted, if the silver particle dispersion adhesive is used as the adhesive layer 286.

As shown in FIG. 27 (a) and (b), the thick adhesive layer 286 is extended to the electrode 172 so that the wire 178 is omitted. The thickness of the adhesive layer 286 is around several tens micrometers.

The present embodiment comprises a bus bar 287 instead of the wire 177 shown in FIG. 19. The bus bar denotes a tabular electrode. The electrode 175 and the semiconductor laser chip 172 are connected via bus bar 287. The bus bar 287 is attached by the bonding process. The bus bar 287 is made from gold plated Mo (molybdenum). The bus bar 287 is formed using an etching method. The Mo has a CTE of 5.1 ppm/K which is close to the CTE of GaAs, 5.9 ppm/K. Also the Mo is possible to be formed by etching process.

The bus bar 287 provides lower electric resistivity due to it has the larger cross-section than the wire 177. The bus bar 287 is mechanically robust.

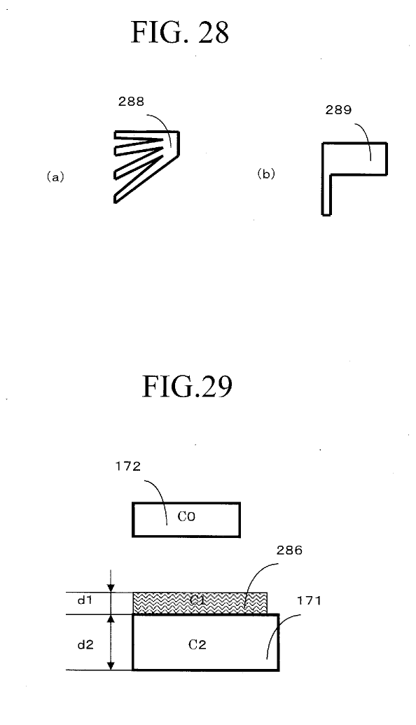

FIG. 28 shows different form of the bus bar. FIG. 28 (a) shows a rake-form bus bar 288. This form allows many smaller contact areas between the bus bar 288 and the semiconductor laser chip 172. Thus thermal stress between the bus bar 288 and the semiconductor laser chip 172 is reduced. Especially, if the CTEs of the bus bar and the semiconductor laser chip are different, this effect becomes notable. Therefore the copper which has CTE of 16.8 ppm/K is applicable to contact the GaAs.

FIG. 28 (b) shows an L-form bus bar 289. The bus bar 289 is made from Mo. The L-form bus bar 289 contacts to the semiconductor laser chip 182 with wider area, thus low and uniform electrical resistivity is obtained.

As shown in FIG. 27 (c), plural semiconductor lasers 281, 282, and 283 are attached on the heat sink 180. The semiconductor lasers 281, 282, and 283 have the same design of the semiconductor laser 280.

This embodiment comprises bus bars 284 and 285 instead of wires 184 and 185 shown in FIG. 19. The bus bar denotes a tabular electrode. The semiconductor lasers 281 and 282 are connected via the bus bar 284. The semiconductor lasers 282 and 283 are connected via the bus bar 285. The bus bars 284 and 285 are attached by using the bonding methods. The bus bars 284 and 285 are made from gold plated copper. The bus bars 284 and 285 are formed using the etching method.

The bus bars 284 and 285 have larger cross-sections than the wires 184 and 185 so that low electrical resistivity is obtained. Also the bus bars 284 and 285 are mechanically robust.

This design using bus bars instead of wires may be applicable to the embodiments shown in FIGS. 1, 2, 10, 16, and 19. The bus bar substitutes the wire 8 shown in FIG. 1. The bus bars substitute the wires 25 and 26 shown in FIG. 2. The bus bars substitute the wires 86, 87, and 88 shown in FIG. 10. The bus bar substitutes the wire 178 shown in FIG. 19.

These designs also provide low electrical resistivity and mechanical robustness.

The bus bars substituting the wire 9 shown in FIG. 1, the wire 147 shown in FIG. 16, and the wire 177 shown in FIG. 19 preferably have close CTEs of the semiconductor laser chips. The bus bars are lacking of flexibility the wires, thus may generate larger thermal stresses.

Material for the bus bars substituting the wires 8, 147, and 177 is preferably Mo, W (Tungsten), CuMo (Copper Molybdenum alloy), or CuW. The Mo is more preferable because its cost and capability of etching as a fabrication process.

### The Fifteenth Embodiment

Referring to FIGS. 27 and 29, a semiconductor laser as the 15^{th} embodiment of the present invention is described. FIG. 29 shows detail of the mount 171, adhesive layer 286, and the semiconductor laser chip 172 shown in FIG. 27.

By adjusting the thicknesses of the adhesive layer 286 and the mount 171, the synthetic CTE of the mount 171 and the adhesive layer 286 is fitted to the CTE of the semiconductor laser chip 172.

The semiconductor laser chip 172 is based on the GaAs, thus its CTE is 5.9 ppm/K. The mount 171 is based on AlN, thus its CTE is 4.5 ppm/K. The CTE of the adhesive layer 286 is depending on the material. The gold fine particle sintered compact, the silver fine particle sintered compact, the silver fine particle dispersion adhesive, and gold tin alloy shows CTE of 14.3 ppm/K, 20 ppm/K, 22 ppm/K. and 17.5 ppm/K, respectively.

The CTEs of the above materials are changed depending on additives or sintering conditions. The above values of CTE are typical ones.

FIG. 29 shows the relationship among the adhesive layer 286, the mount 171, and the semiconductor laser chip 172. Variables, C0, C1, and C2 denote the CTEs of the semiconductor laser chip 172, adhesive layer 286, and the mount 171, respectively. Variables d1 and d2 denote the thicknesses of the adhesive layer 286 and the mount 171, respectively.

In the present embodiment, the thickness of the adhesive layer 286 is defined by the following equation.

d1=kd2(C0−C2)/(C1−C0) (1)

0.7≦k≦1.4
where k is real number.

The above equation is based on the equation disclosed in Japanese Unexamined Patent Application Publication No. 2008-283064. The reference discloses the concept that the synthetic CTE of two layered materials corresponds to a weighted average of CTEs based on volumes of each material. In reality, this concept has some errors so that the equation (1) contains correction coefficient k.

Let us consider that the semiconductor laser chip 172, the mount 171, and the adhesive layer 286 are made from the GaAs, the AlN, and the gold fine particle sintered compact, respectively. Then the value of d1=21˜46 micrometers are obtained, where C0=5.9 ppm/K, C1=14.3 ppm/K, C2=4.5 ppm/K, d2=200 micrometers.

If the silver fine particle sintered compact is used as the adhesive layer 286, the value of d1=14˜28 micrometers are obtained where C1=20 ppm/K while other parameters are maintained. If the gold tin eutectic alloy is used as the adhesive layer 286, the value of d1=15˜30 micrometers are obtained where C1=17.5 ppm/K while other parameters are maintained.

The material of the semiconductor laser chip 172 is not restricted to the GaAs. The material of the mount 171 is not restricted to the AlN. The material of the adhesive layer 286 is not restricted to the gold fine particle sintered compact, the silver fine particle compact, or the gold tin eutectic alloy, Au80-Sn20.

According to the present embodiment, the adhesive layer controls CTE so that sub mounts are eliminated. Lack of the sub mount provides lower thermal resistivity, cost reduction, and simple production process.

The adhesive layer 286 is not restricted to single layer structure. The adhesive layer 286 may be disposed on the metalized mount 171. If the metalized layer is thin enough, it does not affect the synthetic CTE. If the metalized layer has certain thickness, the concept of the equation (1) is extendable to such a structure.

The design controlling the synthetic CTE by the adhesive layer is not only applicable to the semiconductor lasers but also applicable to the other power devices such as IGBTs (Insulated Gate Bipolar Transistors). The above design is applicable to any type of semiconductor device assembly where a semiconductor device attached on a mount.

The adhesive layer comprises the gold fine particle sintered compact, the silver fine particle compact, or the silver particle dispersion adhesive has more advantage that the adhesive layer has a function of stress relaxation.

Typical Young's modulus, or storage modulus, of the gold fine particle sintered compact, the silver fine particle compact, and the silver particle dispersion adhesive are 9.5 GPa, 22 GPa, and 13 GPa, respectively. These values are smaller than the 82 GPa of the GaAs which is the material of the semiconductor laser chip 172.

The adhesive layer 286 made from these low Young's modulus, or storage modulus, adhesives absorbs thermal stress and protects the semiconductor laser chip 172.

As the material of the mount, the AlN's Young's modulus is 320 GPa. As another adhesive material, the tin gold eutectic alloy's Young's modulus is 60 GPa. The E1 is preferably no more than 0.3 times E0, to relax the thermal stress where the E1 is Young's modulus of the adhesive layer 286 and E0 is Young's modulus of the semiconductor laser chip.

More preferably, E1 is no more than 0.2 times E0 to reduce the thermal stress.

The above design is applicable to the semiconductor laser 10 shown in FIG. 1. The adhesive layer of low Yong's modulus between the semiconductor laser chip 2 and the sub mount 3 relaxes the thermal stress of the semiconductor laser chip 2.

Low Young's modulus adhesives typically have larger CTE than the GaAs. If C0=C2 in the equation (1), the result that d1=0 is obtained. Therefore in order to obtain practical d1, C0≠C2 is necessary. Also d1 must be positive value so that C0>C2 is necessary.

As a result, the material for the sub mount 3 should not correspond to the CTE of the semiconductor laser chip.

If CTE of the adhesive layer is smaller than the CTE of the semiconductor laser chip 2, the sub mount 3 should have CTE which is larger than the CTE of the semiconductor laser chip 2.

Referencing to FIG. 1, let us consider the semiconductor laser chip 2 is based on the GaAs whose CTE is 5.9 ppm/K, the sub mount 3 is based on the Mo whose CTE and thickness are 5.1 ppm/K and 200 micrometers, respectively. If the semiconductor laser chip 2 and the sub mount 3 are bonded by the gold fine particle sintered compact whose CTE is 14.3 ppm/K, d1=13.3-26.6 micrometers is obtained.

Accordingly, as the material for sub mount 3, Mo or W is appropriate. From view points of material cost and workability, the Mo is suited for the sub mount. Because wet etching process is applicable for Mo.

The above mentioned design adopting the adhesive layer of low Young's modulus, or storage modulus is not only applicable to the semiconductor laser but also applicable to the power devices such as IGBTs. The above design is applicable to any type of semiconductor device assembly where a semiconductor device attached on a mount.

### The Sixteenth Embodiment

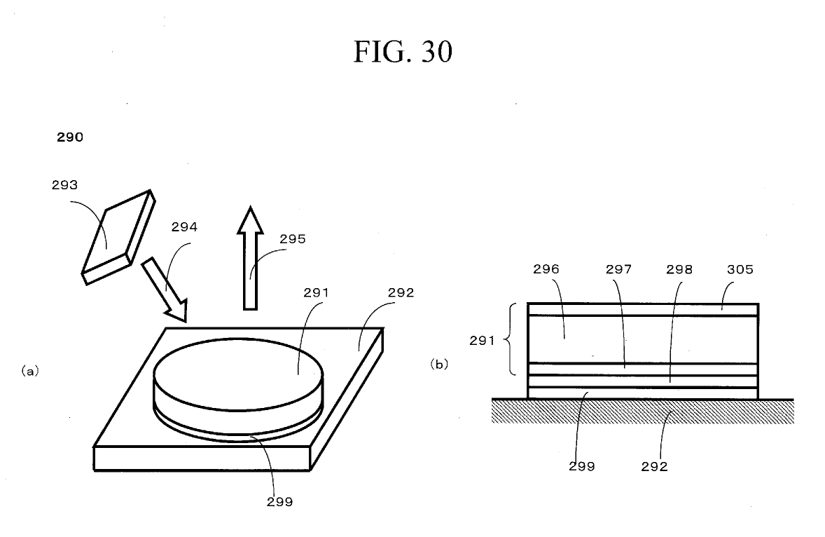

FIG. 30 (a) shows a disk laser 290 as the 16^{th} embodiment of the present invention. The disk 291 made from solid state laser material such as Nd:YAG or Yb:YAG is attached on the heat sink 292 via sub mount 299. Pump light 294 from a Pump light source 293 enters onto the upper surface of the disk 291. An appropriate coupling optics may be disposed between the pump light source 293 and the disk 291. Plural pump light sources 293 may be also disposed.

FIG. 30 (b) shows cross sectional structure of the disk 291. The disk 291 comprises a laser medium 296, a back surface optical coating 297, and a front surface optical coating 305. The disk 291 is bonded to the sub mount 299 via an adhesive layer 298.

The pump light 294 permeate the front surface optical coating 305. The front surface optical coating 305 has certain reflectance against laser light 295. The back surface optical coating 397 has high reflectance against both of the pump light 294 and the laser light 295. The front surface optical coating 305, the laser medium 297, and the back surface optical coating 298 forms a laser resonator which generates the laser light 295.

The heat sink 292 may be a water-cooled or a thermoelectric cooled heat sink.

As the pump light source 293, the laser light source module 20 shown in FIG. 2, the laser light source module 50 shown in FIG. 4, the laser light source module 90 shown in FIG. 10, the laser light source module 110 shown in FIG. 12, the laser light source module 130 shown in FIG. 14, the laser light source module 160 shown in FIG. 17, the laser light source module 190 shown in FIG. 20, or the laser light source module 230 shown in FIG. 23 is applicable.

Laser light source modules emit light perpendicular to the mount surface of semiconductor lasers so that the semiconductor lasers arranged two dimensionally. As a result, high power pump light is realized.

CTE of the disk 291 shown in FIG. 30 (b) is defined as C0. CTE of the adhesive layer 298 is defined as C1. CTE and thickness of the sub mount 299 are defined as C2 and d2. Then we obtained d1 as the thickness of the adhesive layer 298 from the equation (1). The value of d1 relaxes thermal stress between the disk 291 and the sub mount.

The Young's modulus or the storage modulus of the adhesive layer 298 is preferably no more than 0.3 times E0 of the Young's modulus of the disk 291. This condition relaxes thermal stress.

The CTE and the Young's modulus of the YAG as a laser material of the laser medium 296 are 8.0 ppm/K and 308 GPa, respectively. Other materials such as Sapphire or YVO4 are applicable as the laser medium 296.

The variable d1 described in the equation (1) must be positive and real. To satisfy this condition the sub mount 299 preferably has lower CTE than the laser medium 296. Also the adhesive layer 298 preferably has higher CTE than the laser medium 296.

Mo, W, or AlN is preferable as the material for the sub mount to meet the above conditions. The gold fine sintered compact, the silver fine sintered compact, or the silver fine particle dispersion adhesive is preferable as the material of the adhesive layer to meet the above conditions.

The bonding structure between the heat sink 292 and the sub mount 292 also preferably satisfy the equation (1). The Young's modulus of the adhesive layer between the heat sink 292 and the sub mount 299 also preferably is less than 30% of the Young's modulus of the sub mount.

### The Seventeenth Embodiment

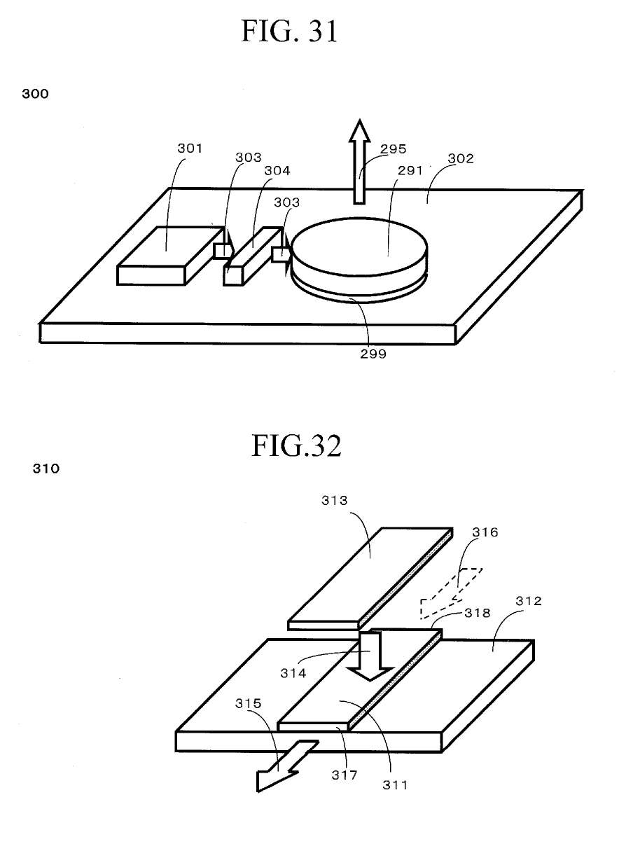

FIG. 31 shows a disk laser 300 as the 17^{th} embodiment of the present invention. The disk 291 made from solid state laser material such as Nd:YAG or Yb:YAG is attached on the heat sink 292 via sub mount 299. Pump light 303 from a Pump light source 301 enters into the side surface of the disk 291 via a coupling optics 304. Plural pump light sources 301 may be also disposed.

The disk laser 300 generates the laser light 295 in a same manner of the sixteenth embodiment. The laser light source 301 is disposed on the heat sink 302. The heat sink 302 cools both the disk 291 and the pump light source 301. Thus a number of components is reduced.

The design in which both the pump light source 301 and the disk 291 are disposed on the common heat sink 302 enables optical alignment easier. Because the common heat sink 302 is used as a datum plane to mount the coupling optics 304.

As the pump light source 301, the semiconductor laser 140, the semiconductor laser 170, or the semiconductor laser 290 is preferably used. These semiconductor lasers emit laser light parallel to the mount so that they are appropriate to realize the design shown in FIG. 31.

These semiconductor lasers emit laser light parallel to the mount so that side pumping of the disk 291 is implemented at ease.

As the heat sink 302, the water cooled or the thermoelectric cooled heat sink is applicable.

### The Eighteenth Embodiment

FIG. 32 shows a thin film slab laser 310 as the 18^{th} embodiment of the present invention. A thin film slab 311 made from solid state laser material such as Nd:YAG or Yb:YAG is attached on the heat sink 312. Pump light 314 from a Pump light source 313 enters onto the upper surface of the thin film slab 311. An appropriate coupling optics may be disposed between the pump light source 313 and the thin film slab 311. Plural pump light sources 313 may be also disposed.

An optical coating which permeates the pump light is disposed on the upper surface of the thin film slab 311. Appropriate optical coatings on side surfaces 317 and 318 of the thin film slab 311 are disposed to generate laser light 315.

As another design, AR (Anti Reflection) coatings on side surfaces 317 and 318 of the thin film slab 311 are disposed to operate the thin film slab 311 as an optical amplifier. In this design, an input light 316 is amplified and emitted as output light 315.

The heat sink 312 may be a water-cooled or a thermoelectric cooled heat sink.

As the pump light source 313, the laser light source module 20 shown in FIG. 2, the laser light source module 50 shown in FIG. 4, the laser light source module 70 shown in FIG. 8, the laser light source module 90 shown in FIG. 10, the laser light source module 110 shown in FIG. 12, the laser light source module 130 shown in FIG. 14, the laser light source module 160 shown in FIG. 17, the laser light source module 190 shown in FIG. 20, or the laser light source module 230 shown in FIG. 23 is applicable.

A sub mount and an adhesive layer may be disposed between the thin film slab 311 and the heat sink 312. This design may adopt the structure comprising the heat sink 292, the sub mount 299, and the adhesive layer 298 shown in FIG. 30.

### The Nineteenth Embodiment

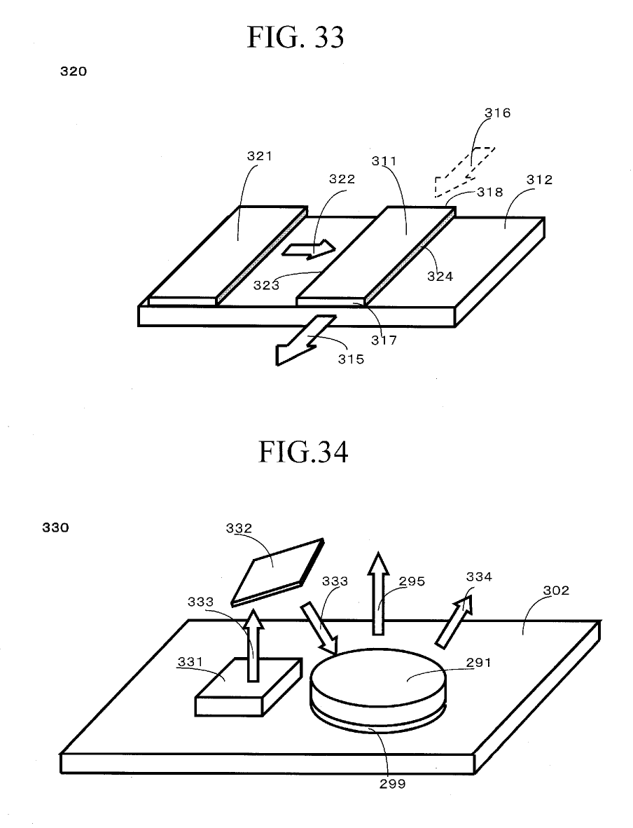

FIG. 33 shows a thin film slab laser 320 as the 19^{th} embodiment of the present invention. A thin film slab 311 made from solid state laser material such as Nd:YAG or Yb:YAG is attached on the heat sink 312. Pump light 322 from a Pump light source 322 enters into the side surface 323 of the thin film slab 311. Between the pump light source 321 and the thin film slab 311 a coupling optics (not shown) is disposed. Plural pump light sources 321 may be also disposed. The pump light may enter into sides 324 or 318.

The design in which the pump light enters into the side surface 318 corresponds to the end pumping method shown in FIG. 21. In this design, the heat sink 312 is extended toward direction to the side surface 318, and the pump light source 321 is disposed at backward of the side surface 318.

A design using an optical direct coupling between the pump light source 321 and the thin film slab 311 is available. The pump light source 321 and the thin film slab 311 are placed close enough; the coupling optics may be eliminated. Die bonding process is applicable for the pump light source 321 and the thin film slab 311 to attach on the heat sink 312. This process enables to place the pump light source 321 close to the thin film slab as small as 0.1 mm.

An optical coating which permeates the pump light is disposed on the side surface 323 of the thin film slab 311. Appropriate optical coatings on the side surfaces 317 and 318 of the thin film slab 311 generate laser light 315.

The design with AR coatings on the side surfaces 317 and 318 enables to operate the thin film slab 311 as an optical amplifier. In this design, the input light 313 is amplified and emitted the output light 315.

The pump light source 321 is disposed on the heat sink 312. The heat sink 312 cools both the thin film slab 311 and the pump light source 321. This design reduces a number of required components.

The design in which both the thin film slab 311 and the pump light source 321 are disposed on the heat sink 312 makes optical alignment easier. The heat sink 312 may be used as a datum plane to attach the coupling optics (not shown).

As the pump light source 321, the semiconductor laser 140 shown in FIG. 16, the semiconductor laser 170, or the semiconductor laser 290 is preferably used. These semiconductor lasers emit laser light parallel to the mount so that they are appropriate to realize the design shown in FIG. 33.

### The Twentieth Embodiment

FIG. 34 shows a disk laser 330 as the 20^{th} embodiment of the present invention. The disk 291 made from solid state laser material such as Nd:YAG or Yb:YAG is attached on the heat sink 292 via sub mount 299. A pump light source 331 is disposed on the heat sink 302. The heat sink cools both the disk 291 and the pump light source 331. This design reduces a number of required components.

Pump light 333 from the pump light source 331 is reflected by a mirror 332 and enter into the disk 291. The laser light 295 is generated according to the mechanism described in the 16^{th} embodiment. The plural pump light sources 331 and mirrors 332 may be disposed.

Optics for recycling the pump light which is not absorbed in the disk 291 may be disposed. Reflectors (not shown) may be also disposed for recycling the pump light 334.

The mirror 332 is attached by appropriate support members. The heat sink 302 is used as the datum for optical alignment.

As the pump light source 313, the laser light source module 20 shown in FIG. 2, the laser light source module 50 shown in FIG. 4, the laser light source module 90 shown in FIG. 10, the laser light source module 110 shown in FIG. 12, the laser light source module 130 shown in FIG. 14, the laser light source module 160 shown in FIG. 17, the laser light source module 190 shown in FIG. 20, or the laser light source module 230 shown in FIG. 23 is applicable.

These laser light source modules arrange the semiconductor lasers two dimensionally. As a result, high power pump light is realized. However these laser light sources emit light perpendicular to the heat sink. To introduce the pump light 333 into the disk 291, the present embodiment comprises the mirror 332.

The thin film slab 311 may substitute the disk 29 in the design shown in FIG. 34.

### The Twenty-First Embodiment

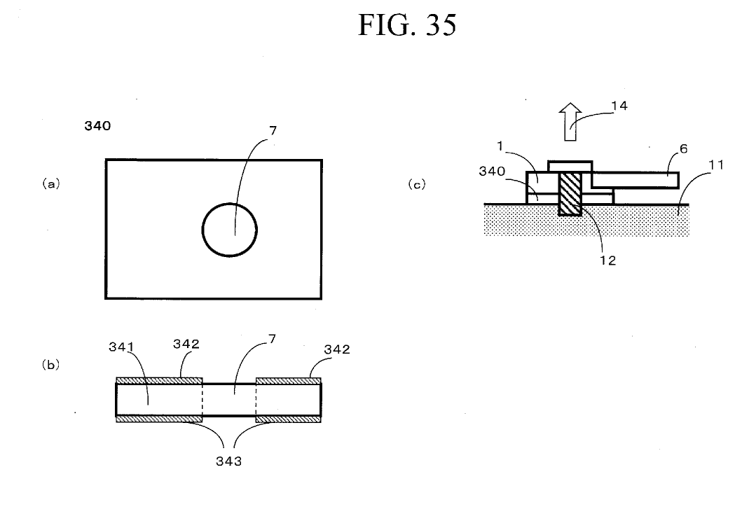

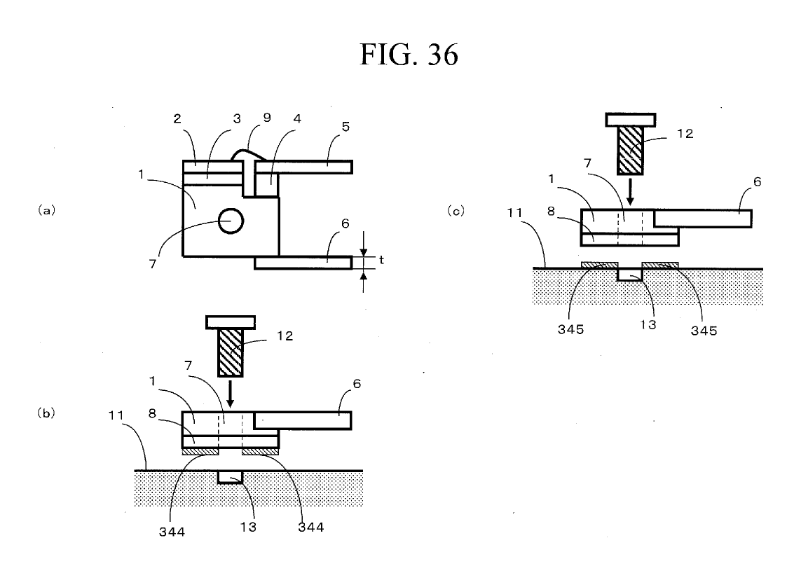

FIG. 35 (a) shows a heat conductive spacer 340 as the 21^{th} embodiment of the present invention. The heat conductive spacer 340 is a derivative of the insulation spacer 8. As shown in FIG. 35 (b), the heat conductive spacer 340 comprises a main body 341, heat conductive parts 342 and 343. The heat conductive part 342 contacts the semiconductor laser. The heat conductive part 342 contacts the heat sink.

The main body 341 is made from AlN. The heat conductive parts 342 and 343 are made from the gold fine particle sintered compact, the silver fine particle sintered compact, or the silver fine particle dispersion adhesive. The thickness of the heat conductive parts 342 and 343 are between 10 and 100 micrometers. The typical thickness is 20 micrometers.

The gold fine particle and silver fine particle sintered compacts have porous structure so that they are flexible and deformed elastically or plastically. As shown in FIG. 35 (c), the heat conductive parts 342 and 343 are deformed by screw clamping the mount 1 of the semiconductor laser to the heat sink 11. As a result the effective contact area between the mount 1 and the heat sink 11 is increased. Thus the heat conductive spacer improves the thermal conductivity.

Due to elastic deformation of the heat conductive parts 342 and 343, they work as well as a washer to prevent slip of screw.

The silver fine particle dispersion adhesive is deformed elastically or plastically. As a result, it improves the thermal conductivity of the heat conductive spacer 340.

The main body 341 of the heat conductive spacer 340 is made of the AlN so that it also works as an insulation spacer. The main body 341 may be copper. In this configuration, the heat conductive spacer 340 works as an electrically conductive spacer.

The heat conductive parts 342 and 343 are formed by the following steps. First of all, the gold fine particle adhesive, the fine silver particle adhesive, or the silver fine particle dispersion adhesive is applied on Front and back surfaces of the main body 341. Second of all, the adhesive is cured and obtained the heat conductive parts 342 and 343.

The gold or silver fine particle adhesives require metallization layers on the both surfaces of the main body 341. The silver fine particle dispersion adhesive does not require such metallization layers.

The heat conductive spacer 340 improves thermal conductivity in the case of the mount 1 is attached by clamping. The attachment by clamping provides better reworkability.

FIG. 35 (a) and (c) show a configuration in which the insulation spacer 8 is bonded to the mount 1 and a heat conductive part 244 is formed on back surface of the insulation spacer 8. The heat conductive part 244 is made from the gold fine particle sintered compact, the silver fine particle compact, or the silver fine particle dispersion adhesive.

The mount 1 is attached on a heat sink by screw 12. The heat conductive part 344 is deformed and increases effective contact area and improves thermal conductivity.

FIG. 36 (c) shows a configuration in which a heat conductive part 345 is disposed on the heat sink 11. The heat conductive part 345 is made from the gold fine particle sintered compact, the silver fine particle compact, or the silver fine particle dispersion adhesive.

The mount 1 is attached on a heat sink by screw 12. The heat conductive part 345 is deformed and increases effective contact area and improves thermal conductivity.

The configuration shown in FIG. 36 provides better reworkability.

The configuration shown in FIG. 36 (b) is applicable to the semiconductor laser 120 shown in FIG. 12, the semiconductor laser 220 shown in FIG. 22, and the sub mount 299 shown in FIG. 30.

The design of the present embodiment is not only applicable to the semiconductor lasers but also applicable to the power semiconductor devices such as IGBTs, and solid state mediums.

### Additional Embodiments

The present invention provides for the following additional exemplary embodiments, the numbering of which is not to be construed as designing levels of importance.

The additional embodiment 1 provides a semiconductor laser comprising a semiconductor laser chip, conductive mount, insulation block, upper electrode, and lower electrode, wherein said semiconductor laser chip and said insulation block are bonded to the 1^{st} surface of said conductive mount, said upper electrode is bonded to said insulation block, an upper surface of said upper electrode and said semiconductor laser chip are connected via conductive wire, and said lower electrode is bonded to the 2^{nd} surface of said conductive mount.

The additional embodiment 2 provides a laser light source module comprising plural semiconductor lasers of the additional embodiment 1 on a heat sink, wherein said heat sink and said plural semiconductor lasers are insulated, and side surface of an upper electrode of one of said semiconductor lasers and a lower electrode of an adjacent said semiconductor laser are connected via a conductive wire.

The additional embodiment 3 provides a laser light source module of the additional embodiment 2, wherein said heat sink is water cooled heat sink, and said semiconductor lasers comprises mounting holes, and wherein said heat sink comprises hairpin shaped channel such that heat generation regions of the said semiconductor lasers are placed above said channel, and wherein the holes are provided to locate said semiconductor lasers among said channel.

The additional embodiment 4 provides a solid state laser comprising a solid state medium and a pump light source, wherein said pump light source is said laser light source of the additional embodiment 2.

The additional embodiment 5 provides a semiconductor laser comprising a semiconductor laser chip, a conductive mount, insulation block, an electrode, and an insulation spacer, wherein said semiconductor laser chip and said insulation block are bonded to the 1^{st} surface of said conductive mount, said electrode is bonded to said insulation block, an upper surface of said electrode and said semiconductor laser chip are connected via a conductive wire, and said insulation block is bonded to the 3^{rd} surface of said conductive mount.

The additional embodiment 6 provides a semiconductor laser of the additional embodiment 5, wherein said insulation block is made from AlN.

The additional embodiment 7 provides a semiconductor laser of the additional embodiment 5, wherein a thickness of said insulation spacer is between 0.2 mm and 0.5 mm.

The additional embodiment 8 provides a semiconductor laser of the additional embodiment 5, wherein said conductive mount and said insulation block are bonded by silver fine particle dispersion adhesives.

The additional embodiment 9 provides a semiconductor laser of the additional embodiment 5, wherein said insulation spacer comprises a gold metalized surface, and said gold metalized surface and said conductive mount are bonded.

The additional embodiment 10 provides a semiconductor laser comprising a semiconductor laser chip, a conductive mount, a insulation block, and an electrode, wherein said semiconductor laser chip and said insulation block are bonded to the 1^{st} surface of said conductive mount, and an upper surface of said electrode and said semiconductor laser chip are connected via a conductive wire, wherein a thickness of said electrode is no less than 0.3 mm.

The additional embodiment 11 provides a semiconductor laser comprising a semiconductor laser chip, a mount, a sub mount, an insulation block, and an electrode, wherein said sub mount is bonded to said mount, said semiconductor chip is bonded to said sub mount, said insulation block is bonded to said mount, said electrode is bonded to said insulation block, and an upper surface of said electrode and said semiconductor laser are connected via a conductive wire, and wherein said mount, said sub mount, said insulation block, and said electrode are bonded by simultaneous soldering.

The additional embodiment 12 provides a semiconductor laser of the additional embodiment 11, wherein said simultaneous soldering is conducted by use of a carbon jig.

The additional embodiment 13 provides a semiconductor laser of the additional embodiment 11, wherein said mount, said sub mount, and said electrode are plated simultaneously.

The additional embodiment 14 provides a laser light source module comprising plural semiconductor lasers and a heat sink, wherein each of said semiconductor laser comprise a semiconductor chip, conductive mount, insulation block, and an electrode, wherein said semiconductor laser chip and said insulation block are bonded to the 1^{st} surface of said mount, an upper surface of said electrode and said semiconductor chip are connected via conductive wire, and wherein said heat sink and plural said semiconductor lasers are insulated, and a side surface of said electrode of one of said semiconductor lasers and said mount of adjacent semiconductor laser are connected via a conductive wire.

The additional embodiment 15 provides a semiconductor laser comprising a semiconductor laser chip, a conductive mount, an insulation block, and an electrode, wherein said semiconductor laser chip and said insulation block are bonded to the 1^{st} surface of said conductive mount, said electrode is bonded to said insulation block, an upper surface of said electrode and said semiconductor laser chip are connected a via conductive wire, and wherein said conductive mount comprises two or more mounting holes, and wherein said holes are placed at positions other than immediately beneath regions of said semiconductor laser chip.

The additional embodiment 16 provides a laser light source module comprising plural semiconductor lasers of the additional embodiment 15 attached on a heat sink, wherein said heat sink and plural said semiconductors are insulated, and a side surface of said electrode of one of said semiconductor lasers and said mount of adjacent semiconductor laser are connected via a conductive wire.

The additional embodiment 17 provides a laser light source module of the additional embodiment 16, wherein said heat sink is water cooled heat sink, and said heat sink comprises straight lined channel with threaded holes to mount said semiconductor lasers on either side.

The additional embodiment 18 provides a solid state laser comprising a solid state laser medium and a pump light source, wherein said pump light source is laser light source module of the additional embodiment 15.

The additional embodiment 19 provides a semiconductor laser comprising a semiconductor laser chip and insulation mount, wherein the 1^{st} and 2^{nd} electrodes are formed on said insulation mount, said semiconductor laser chip is bonded to said 1^{st} electrode, said semiconductor laser chip and said 2^{nd} electrode are connected via a wire, and a mounting hole corresponding to each of said electrode is disposed.

The additional embodiment 20 provides a laser light source module comprising plural semiconductor lasers of the additional embodiment 19 on a heat sink, wherein one of said semiconductor lasers and an adjacent semiconductor laser are connected via bus bar.

The additional embodiment 21 provides a laser light source module of the additional embodiment 20, wherein said heat sink is water cooled heat sink, and said heat sink comprises straight lined channel with threaded holes to mount said semiconductor lasers on one side.

The additional embodiment 22 provides a solid state laser comprising a solid state laser medium and a pump light source, wherein said pump light source is said laser light source module of the additional embodiment 20.

The additional embodiment 23 provides a semiconductor laser comprising an insulation mount, a conductive sub mount, an insulation plate, the 1^{st} electrode, and the 2^{nd} electrode, wherein said semiconductor laser chip is bonded to said conductive sub mount, said conductive sub mount is bonded to said insulation mount, said 1^{st} electrode is bonded to said insulation plate, said insulation plate is bonded to said insulation mount, and said 2^{nd} electrode is bonded to said insulation plate, wherein said semiconductor laser chip and said 1^{st} electrode are connected via the 1^{st} wire, said conductive sub mount and said 2^{nd} electrode are connected via the 2^{nd} wire.

The additional embodiment 24 provides a laser light source module comprising plural said semiconductor lasers of the additional embodiment 23 on a heat sink, wherein one of said semiconductor lasers and an adjacent semiconductor laser are connected via a wire.

The additional embodiment 25 provides a solid state laser comprising a solid state laser medium and a pump light source, wherein said pump light source is said laser light source of the additional embodiment 24.

The additional embodiment 26 provides a laser light source module comprising two semiconductor lasers on a heat sink, wherein each of said semiconductor laser comprises a semiconductor laser chip, a conductive mount, an insulation block, and an electrode, where said semiconductor laser chip and said insulation block are bonded to a surface of said conductive mount, said electrode is bonded to said insulation block, an upper surface of said electrode and said semiconductor laser chip are connected via a conductive wire, and wherein said 1^{st} semiconductor laser and said 2^{nd} semiconductor laser are disposed in a manner of face to face.

The additional embodiment 27 provides a solid state laser of the additional embodiment 26, wherein said solid state laser medium is pumped by end pumping method.

The additional embodiment 28 provides a semiconductor laser comprising a semiconductor laser chip, a conductive mount, the 1^{st} insulation block, the 2^{nd} insulation block, and an electrode, wherein said semiconductor laser chip and said 1^{st} insulation block are bonded to the 1^{st} surface of said conductive mount at one end, said electrode is bonded to said 1^{st} insulation block, an upper surface of said electrode and said semiconductor laser chip are connected via a conductive wire, and wherein said 2^{nd} insulation block is bonded to said 1^{st} surface of said conductive mount at another end.

The additional embodiment 29 provides a semiconductor laser of the additional embodiment 28, wherein a height of said 2^{nd} insulation block is equivalent to a sum of a height of said 1^{st} insulation block and a height of said electrode.

The additional embodiment 30 provides a semiconductor laser comprising a semiconductor laser chip, a conductive mount, insulation block, and an electrode, wherein said electrode has step structure with upper surface and lower surface, and said semiconductor laser and insulation block are bonded to said conductive mount, said electrode is bonded to said insulation block, said semiconductor laser and said electrode are connected via a conductive wire, and wherein said conductive wire is bonded to said lower face of said electrode.

The additional embodiment 31 provides a semiconductor laser comprising a semiconductor laser chip, an insulation mount, an insulation plate, the 1^{st} electrode, and the 2^{nd} electrode, wherein said semiconductor chip is bonded to said insulation mount, said 1^{st} electrode is bonded to said insulation plate, said insulation plate is bonded to said insulation mount, said 2^{nd} electrode is bonded to said insulation mount, and wherein, said semiconductor laser chip and said 1^{st} electrode is connected via a tabular electrode.

The additional embodiment 32 provides a semiconductor laser chip comprising a semiconductor laser chip, a conductive mount, an insulation block, and, an electrode, wherein said semiconductor chip and said insulation block are bonded to a surface of said conductive mount, said electrode is bonded to said insulation block, and, an upper surface of said electrode and said semiconductor laser are connected via a tabular electrode.

The additional embodiment 33 provides a semiconductor laser chip comprising a semiconductor laser chip, a insulation mount, wherein said insulation mount comprises the 1^{st} electrode pattern and 2^{nd} electrode pattern, said semiconductor laser chip is bonded to said 1^{st} electrode pattern, and said semiconductor laser and said 2^{nd} electrode pattern are connected via a tabular electrode.

The additional embodiment 34 provides a laser light source module comprising plural semiconductor lasers on a heat sink, wherein said semiconductor laser comprises an upper electrode and a lower electrode, and said heat sink and plural said semiconductor lasers are insulated, and a side surface of said upper electrode of certain said semiconductor laser and a side surface of said lower electrode of adjacent said semiconductor laser via a tabular electrode.

The additional embodiment 35 provides a laser light source module comprising plural semiconductor lasers and a heat sink, wherein said semiconductor laser comprises a semiconductor laser chip, conductive mount, an insulation block, and electrode, and said semiconductor laser chip and said insulation block are bonded to a surface of said conductive mount, said electrode is bonded to said insulation block, an upper surface of said electrode and said semiconductor laser chip are connected, and further said heat sink and said semiconductor lasers are insulated, and a side surface of said electrode of one of said semiconductor lasers is connected to said conductive mount of an adjacent semiconductor laser via a tabular electrode.

The additional embodiment 36 provides a laser light source module comprising plural semiconductor lasers and a heat sink, wherein said semiconductor laser comprises a semiconductor laser chip, an insulation plate, the 1^{st} electrode, and 2^{nd} electrode, wherein said semiconductor laser chip is bonded to said insulation mount, said 1^{st} and 2^{nd} electrodes are formed on said insulation plate, said insulation plate is bonded to said insulation mount, said 2^{nd} electrode is bonded to said insulation mount, and said semiconductor laser chip and said 1^{st} electrode are connected, and further said heat sink and said semiconductor lasers are insulated, and furthermore the 1^{st} electrode of one of said semiconductor lasers and the 2^{nd} electrode of an adjacent semiconductor laser are connected via a tabular electrode.

The additional embodiment 37 provides a laser light source module comprising plural semiconductor lasers and a heat sink, wherein said semiconductor laser comprises a semiconductor laser chip, an insulation plate, the 1^{st} electrode, and 2^{nd} electrode, wherein said semiconductor laser chip is bonded to said insulation mount, said 1^{st} electrode is bonded to said insulation plate, said insulation plate is bonded to said insulation mount, said 2^{nd} electrode is bonded to said insulation mount, and said semiconductor laser chip and said 1^{st} electrode are connected, said heat sink and said semiconductor lasers are insulated, and, the 1^{s1} electrode of one of said semiconductor lasers and the 2^{nd} electrode of an adjacent semiconductor laser are connected via a tabular electrode.

The additional embodiment 38 provides a semiconductor laser comprising a semiconductor laser chip and an electrode connected with a tabular electrode, wherein a CTE of said tabular electrode almost corresponds to a CTE of said semiconductor laser chip.

The additional embodiment 39 provides a device assembly comprising a device and a mount bonded via an adhesive layer, wherein the following expression is satisfied where: C0, C2, C1, d2, and d1 denotes a CTE of said device, a CTE of said mount, a CTE of said adhesive layer, thickness of said mount, and thickness of said adhesive layer, respectively.

d1=kd2(C0−C2)/(C1−C0) (1)

where k is real number and 0.7≦k≦1.4.

The additional embodiment 40 provides a device assembly comprising a device and a mount bonded via an adhesive layer, wherein a Young's modulus, or a storage modulus, E1 of said adhesive layer is no more than 0.3*E0 where E0 is a Young's modulus of said device.

The additional embodiment 41 provides a device assembly comprising a device and a mount bonded via an adhesive layer, wherein a CTE of said mount is smaller than a coefficient of said device, and a CTE of said adhesive layer is larger than said thermal expansion of said device.

The additional embodiment 42 provides a device assembly comprising a device and a mount bonded via an adhesive layer, wherein a CTE of said mount is larger than a coefficient of said device, and a CTE of said adhesive layer is smaller than said thermal expansion of said device.

The additional embodiment 43 provides a solid state laser comprising a thin film laser medium, pump light soured, and a heat sink, wherein said thin film laser medium and said pump light source are attached on said heat sink.

The additional embodiment 44 provides a solid state laser of the additional embodiment 43, wherein said pump light source emits light parallel to a mounting surface.

The additional embodiment 45 provides a solid state laser of the additional embodiment 43, further comprising a coupling optics to couple said thin film laser medium and said pump light source, wherein a surface of said heat sink is used as a datum plane of optical alignment of said coupling optics.

The additional embodiment 46 provides a solid state laser of the additional embodiment 43, wherein said pump light source emits light perpendicular to a mounting surface, further comprising a mirror to couple said solid state laser medium and said pump light surface.

The additional embodiment 47 provides a heat conductive spacer comprising a heat conductive layer made from a selected from a gold fine particle sintered compact, a silver fine particle sintered compact, or a silver fine particle dispersion adhesive.

The additional embodiment 48 provides a device to be attached on a heat sink, wherein a surface to be attached on said heat sink of said device comprises a heat conductive layer made from a selected from a gold fine particle sintered compact, a silver fine particle sintered compact, or a silver fine particle dispersion adhesive.

The additional embodiment 49 provides a heat sink comprising a heat conductive layer made from a selected from a gold fine particle sintered compact, a silver fine particle sintered compact, or a silver fine particle dispersion adhesive.

While the illustrative embodiments of the invention have been described with particularity, it will be understood that various other modifications will be apparent to and can be readily made by those of ordinary skill in the art without departing from the spirit and scope of the invention. Accordingly, it is not intended that the scope of the claims appended hereto be limited to the examples and descriptions set forth herein, but rather that the claims be construed as encompassing all of the features of patentable novelty which reside in the present invention, including all features which would be treated as equivalents thereof by those of ordinary skill in the art to which the invention pertains.

What is claimed is:

1. A semiconductor laser comprising a semiconductor laser chip, a conductive mount, an insulation block, and an electrode, wherein said semiconductor laser chip and said insulation block are bonded to a surface of said conductive mount, and an upper surface of said electrode and said semiconductor laser chip are electrically connected, and further wherein a thickness of said electrode is no less than 0.3 mm.

2. The semiconductor laser of claim 1, wherein conductive members are bonded to a side surface of said electrode to provide electrical connection to an external electric circuit.

3. The semiconductor laser of claim 2, wherein said conductive members are conductive wires.

4. The semiconductor laser of claim 2, wherein said conductive members are tabular electrodes.

5. A semiconductor laser comprising a semiconductor laser chip, a conductive mount, insulation block, an electrode, and an insulation spacer, said semiconductor laser chip and said insulation block are bonded to a surface of said conductive mount, said electrode is bonded to said insulation block, an upper surface of said electrode and said semiconductor laser chip are electrically connected, and said insulation block is bonded to another surface of said conductive mount to be contacted to a heat sink.

6. The semiconductor laser of claim 5, further comprising another electrode disposed on an opposite surface to said surface in which said semiconductor laser chip is disposed.

7. The semiconductor laser of claim 5, wherein said insulation block is made from an aluminum nitride.

8. The semiconductor laser of claim 5, wherein a thickness of said insulation spacer is between 0.2 mm and 0.5 mm.

9. The semiconductor laser of claim 5, wherein an adhesive layer made from a selected from a group consisting of a gold fine particle sintered compact, a silver fine particle sintered compact, and a silver fine particle dispersion adhesive is disposed between said insulation spacer and said conductive mount.

10. A semiconductor laser comprising a semiconductor laser chip, a conductive mount, an insulation block, and an electrode, said semiconductor laser chip and said insulation block are bonded to a surface of said conductive mount, wherein said electrode is bonded to said insulation block, an upper surface of said electrode and said semiconductor laser chip are electrically connected, and wherein said conductive mount comprises two or more mounting holes at another surface perpendicular to said surface in which said semiconductor laser is disposed, and further wherein said holes are placed at positions other than immediately beneath regions of said semiconductor laser chip.
